(19) United States
(12) Patent Application Publication
(10) Pub. No.: US 2025/0372465 A1
(43) Pub. Date: Dec. 4, 2025

(54) TEMPERATURE SENSING WITHIN AN ELECTRONIC COMPONENT

(71) Applicant: SEMICONDUCTOR COMPONENTS INDUSTRIES, LLC, Scottsdale, AZ (US)

(72) Inventors: Gyuwan HAN, Incheon (KR); JeongHyuk PARK, Incheon (KR); Seungwon IM, Bucheon (KR); Keunhyuk LEE, Suzhou (CN)

(73) Assignee: SEMICONDUCTOR COMPONENTS INDUSTRIES, LLC, Scottsdale, AZ (US)

(21) Appl. No.: 18/970,098

(22) Filed: Dec. 5, 2024

Related U.S. Application Data
(63) Continuation-in-part of application No. 18/731,625, filed on Jun. 3, 2024.

(51) Int. Cl. H01L 21/66; H01L 23/00

(52) U.S. Cl. CPC H01L 22/34; H01L 24/48; H01L 24/32; H01L 24/40; H01L 24/46; H01L 24/49; H01L 2224/32225; H01L 2224/40225; H01L 2224/46; H01L 2224/48245; H01L 2224/49109; H01L 2924/1207

(57) ABSTRACT

Apparatuses disclosed herein are configured to support temperature sensing, including on-die temperature sensing, within an electronic component. An illustrative apparatus may include a substrate, a semiconductor die disposed on the substrate, a leadless temperature sensor, and a plurality of leads including at least a first lead and a second lead. The semiconductor die may implement a transistor and the leadless temperature sensor may be configured to measure a temperature of the transistor, in some cases by being disposed directly on the semiconductor die. The first lead may be electrically coupled with a first surface of the leadless temperature sensor while the second lead may be electrically coupled with a second surface of the leadless temperature sensor. Corresponding methods for fabricating such apparatuses are also disclosed.

### RELATED APPLICATIONS

This application is a continuation-in-part application claiming priority to, and the benefit of, U.S. application Ser. No. 18/731,625, which was filed Jun. 3, 2024, and which is incorporated by reference in its entirety herein.

### BACKGROUND

Electronic components may incorporate sensing technologies to enhance their performance, reliability, and efficiency. For example, one sensing technology that may be advantageously incorporated in certain electronic components (e.g., power electronics, etc.) is temperature sensing technology. By monitoring the internal temperature of an electronic component, a device utilizing the electronic component may implement thermal management strategies to prevent overheating and optimize performance. Temperature sensors could also be used to detect potential faults or anomalies within the device, enabling early intervention and reducing the risk of catastrophic failures. Other sensing technologies (e.g., current sensing, voltage sensing, etc.) may also be incorporated in certain electronic components to provide corresponding advantages.

### SUMMARY

Various electronic components (e.g., power transistors, integrated circuits, etc.) are packaged such that a molding material encloses internal electronics, while leads or other suitable electrical connections (e.g., pins, bumps, etc.) protrude from the molding material to facilitate the electronic component being connected to external circuitry. For example, internal circuitry of a particular electronic component could include one or more semiconductor dies (e.g., each implementing one or more transistors or other elements), discrete components (e.g., resistors, capacitors, diodes, etc.), electrical connections between the various elements (e.g., wirebonds, clips, etc.), and so forth. These and/or other elements within an electronic component could be disposed on a substrate or leadframe that is configured to provide structural support and to facilitate electrical connections between the various internal elements and the leads.

In some cases, it may also be desirable for certain sensors to be included in the electronic component. For instance, a temperature sensor (e.g., a thermistor, etc.) may be integrated into the device package of the electronic component for use in measuring and indicating an internal temperature of the component. Temperature sensors would conventionally be placed on the substrate with the semiconductor dies and other circuit elements, therefore requiring at least some area of the substrate to be properly connected to the rest of the circuit (e.g., area of the substrate used for pads, traces, etc.). As detailed herein, however, leadless temperature sensors and other leadless discrete components may be utilized to support desired sensing and circuit functions (including temperature sensing) by sensor components that are placed closer to the semiconductor dies and require little or no additional substrate area to be connected. Indeed, in some examples, a leadless temperature sensor may even be placed directly on a semiconductor die (rather than on the substrate) to thereby achieve the most accurate and timely temperature measurements of that die.

In one example implementation, an apparatus (e.g., an electronic device, a packaged semiconductor device, etc.) includes: 1) a substrate; 2) a semiconductor die disposed on the substrate, the semiconductor die implementing a transistor; 3) a leadless temperature sensor having a first surface and a second surface opposite the first surface, the leadless temperature sensor being configured to measure a temperature of the semiconductor die; and 4) a plurality of leads including a first lead and a second lead, the first lead electrically coupled with the first surface of the leadless temperature sensor and the second lead electrically coupled with the second surface of the leadless temperature sensor.

In another example implementation, an apparatus (e.g., an electronic device, a packaged semiconductor device, etc.) includes: 1) a substrate having a first portion and a second portion, the first portion being electrically isolated from the second portion; 2) a leadless discrete component having a first surface and a second surface opposite the first surface, the first surface being physically coupled and electrically coupled to the first portion of the substrate; 3) a semiconductor die physically coupled and electrically coupled to the second portion of the substrate; and 4) a plurality of leads including a first lead electrically coupled to the first portion of the substrate, a second lead electrically coupled to the second portion of the substrate, and a third lead electrically coupled to the second surface of the leadless discrete component.

In another example implementation, an apparatus includes: 1) a substrate having a first portion and a second portion, the first portion being electrically isolated from the second portion; 2) a semiconductor die physically coupled to the second portion of the substrate; 3) a plurality of leads including a first lead electrically coupled to the first portion of the substrate, a second lead electrically coupled to the second portion of the substrate, and a third lead; and 4) a leadless discrete component having a first surface and a second surface opposite the first surface, the leadless discrete component being sandwiched between the substrate and the third lead, such that: (a) the first surface of the leadless discrete component is physically coupled and electrically coupled to the first portion of the substrate, and (b) the second surface of the leadless discrete component is physically coupled and electrically coupled to the third lead.

In another example implementation, an apparatus includes: 1) a substrate; 2) a semiconductor die disposed on the substrate, the semiconductor die implementing a transistor and including a pad on a surface of the semiconductor die facing away from the substrate; 3) a leadless temperature sensor disposed on the pad of the semiconductor die; and 4) a plurality of leads including a first lead electrically coupled with a surface of the leadless temperature sensor facing away from the surface of the semiconductor die and a second lead electrically coupled with the surface of the semiconductor die.

In another example implementation, a method includes: 1) forming a substrate for use in a semiconductor package, the substrate including a first portion and a second portion, the first portion being electrically isolated from the second portion; 2) coupling a first surface of a leadless discrete component to the first portion of the substrate; 3) coupling a semiconductor die to the second portion of the substrate; 4) coupling a first conductive component to a first lead of a plurality of leads and to the first portion of the substrate; 5) coupling a second conductive component to a second lead of the plurality of leads and to the second portion of the substrate; and 6) coupling a third conductive component to a third lead of the plurality of leads and to a second surface of the leadless discrete component, the second surface being opposite the first surface.

In another example implementation, a method includes: 1) coupling a semiconductor die with a substrate, the semiconductor die implementing a transistor and including a pad on a surface of the semiconductor die facing away from the substrate; 2) coupling a leadless temperature sensor with the pad of the semiconductor die; 3) coupling a first conductive component with a first lead of a plurality of leads and with a surface of the leadless temperature sensor facing away from the surface of the semiconductor die; and 4) coupling a second conductive component with a second lead of the plurality of leads and with the surface of the semiconductor die.

Each of the preceding example implementations and the various aspects described therewith will be understood to be illustrative of the types of implementations that are consistent with the following description. It will be understood that these examples are not intended to be limiting and that any of the aspects mentioned above or described herein may be used with any of the implementations in accordance with principles described herein. The details of these and other implementations are set forth in the accompanying drawings and the description below. Other features will also be apparent from the following description, drawings, and claims.

### BRIEF DESCRIPTION OF THE DRAWINGS

FIG. 1A shows illustrative elements of an apparatus implementing temperature sensing within an electronic component in accordance with principles described herein.

FIG. 1B shows illustrative elements of an apparatus implementing compact semiconductor packaging using a leadless discrete component in accordance with principles described herein.

FIG. 1C shows illustrative elements of an apparatus implementing on-die temperature sensing within an electronic component in accordance with principles described herein.

FIG. 2 contrasts illustrative aspects of conventional semiconductor packaging with compact semiconductor packaging using leadless discrete components in accordance with principles described herein.

FIG. 3A shows illustrative aspects of compact semiconductor packaging using a leadless discrete component and wire-based electrical couplings in accordance with principles described herein.

FIG. 3B shows, in a cross-sectional view, illustrative aspects of a solder-based implementation of the compact semiconductor packaging of FIG. 3A in accordance with principles described herein.

FIG. 3C shows, in a cross-sectional view, illustrative aspects of a sinter-based implementation of the compact semiconductor packaging of FIG. 3A in accordance with principles described herein.

FIG. 3D shows, in a cross-sectional view, illustrative aspects of an adhesive-based implementation of the compact semiconductor packaging of FIG. 3A in accordance with principles described herein.

FIG. 4A shows illustrative aspects of compact semiconductor packaging using a leadless discrete component and clip-based electrical couplings in accordance with principles described herein.

FIG. 4B shows, in a cross-sectional view, illustrative aspects of a solder-based implementation of the compact semiconductor packaging of FIG. 4A in accordance with principles described herein.

FIG. 4C shows, in a cross-sectional view, illustrative aspects of a sinter-based implementation of the compact semiconductor packaging of FIG. 4A in accordance with principles described herein.

FIG. 4D shows, in a cross-sectional view, illustrative aspects of an adhesive-based implementation of the compact semiconductor packaging of FIG. 4A in accordance with principles described herein.

FIG. 5A shows illustrative aspects of compact semiconductor packaging using a leadless discrete component sandwiched between a lead and the substrate in accordance with principles described herein.

FIG. 5B shows, in a cross-sectional view, illustrative aspects of a solder-based implementation of the compact semiconductor packaging of FIG. 5A in accordance with principles described herein.

FIG. 5C shows, in a cross-sectional view, illustrative aspects of a sinter-based implementation of the compact semiconductor packaging of FIG. 5A in accordance with principles described herein.

FIG. 5D shows, in a cross-sectional view, illustrative aspects of an adhesive-based implementation of the compact semiconductor packaging of FIG. 5A in accordance with principles described herein.

FIG. 6 shows illustrative aspects of an apparatus packaged using compact semiconductor packaging in accordance with principles described herein.

FIG. 7 shows an illustrative method for constructing an apparatus with compact semiconductor packaging using a leadless discrete component in accordance with principles described herein.

FIG. 8 contrasts illustrative aspects of conventional temperature sensor placement within a device package with on-die leadless temperature sensor placement within a device package in accordance with principles described herein.

FIG. 9A shows, in a cross-sectional view, illustrative aspects of one example implementation of on-die temperature sensing within an electronic component in accordance with principles described herein.

FIG. 9B shows, in a cross-sectional view, illustrative aspects of another example implementation of on-die temperature sensing within an electronic component in accordance with principles described herein.

FIG. 10 shows illustrative aspects of an implementation of a multi-die electronic component featuring on-die temperature sensing in accordance with principles described herein.

FIG. 11 shows illustrative aspects of an implementation of a multi-die electronic component featuring dual on-die temperature sensing in accordance with principles described herein.

FIG. 12 shows illustrative aspects of a packaged apparatus configured to perform on-die temperature sensing in accordance with principles described herein.

FIG. 13A shows an illustrative method for constructing an apparatus employing on-die temperature sensing using a leadless temperature sensor in accordance with principles described herein.

FIG. 13B shows an illustrative method for constructing a multi-die apparatus employing on-die temperature sensing using multiple leadless temperature sensors in accordance with principles described herein.

### DETAILED DESCRIPTION

Electronic components such as integrated circuits are packaged such that one or more semiconductor dies are encased in a molding material and are electrically connected to leads (or other suitable conductors such as pins, bumps, etc.) that extend out from the molding material to facilitate connecting the electronic component to other external circuitry. For instance, the electronic component may connect, by way of the leads, to a printed circuit board (PCB) to which other electronic components are also connected, or to other external circuitry connected by other suitable mechanisms (besides via a PCB).

For certain electronic components packaged in this way, the encased electronics may include one or more semiconductor dies, as well as other electronic components (e.g., discrete components such as thermistors, resistors, capacitors, etc.) configured to facilitate circuit functions for which the semiconductor dies are designed. As will be described in more detail below, the semiconductor dies and other components may be disposed on a leadframe or other type of substrate. A leadframe, for example, may provide a die pad on which a semiconductor die is placed, and individual leads may be connected to the die by way of wire bonding or other suitable techniques. In other examples, other types of substrates could be used that allow for more complex patterns of connections to be made between multiple dies and/or between the die(s) and other electronic components. For instance, a direct-bonded metal (DBM) substrate (e.g., a direct-bonded copper (DBC) substrate, etc.) may be used in which layers of metal are direct-bonded to a non-conductive substrate such as a ceramic plate. The metal layer may be etched or otherwise processed to remove portions of the metal and thereby form planes and traces that may help implement the desired electrical couplings within the package.

For various electronic components produced based on these principles, there are certain technical problems that may arise for which leadless discrete components (e.g., leadless temperature sensors, leadless resistors or capacitors, etc.) may provide technical solutions. As will be described in detail herein, two categories of technical problems that may be addressed, mitigated, and/or solved using leadless discrete components will now be described, followed by detailed description with reference to the figures.

A first category of technical problems that may be addressed by use of leadless discrete components relates to the challenge of making device packages as compact, streamlined, and efficient as possible.

If the package sizing (e.g., footprint, profile, etc.) for an integrated circuit component that includes at least one die and at least one discrete component in a unified package is not of particular importance for a given implementation, conventional surface mount technology (SMT) components (i.e., discrete components conforming to SMT package types such as 0402, 0603, etc.) may be used. For example, small traces and pads on a substrate within the package of the integrated circuit component may facilitate desired electrical connections between a die (or dies) in the package and one or more SMT components, as well as between these devices and leads emerging from the package.

A technical problem may arise, however, if it is desired that the package sizing for the integrated circuit component is small and typical SMT-based discrete components are used. Specifically, SMT components and other commonly-available discrete components with their own leads may make it difficult for a package to be made compact since these discrete components require a certain amount of space on the substrate for proper connections to be made. For example, suitably-sized pads for each lead of each discrete component may be required, as well as clearances between these pads (so that undesirable shorts between the leads do not occur), traces to form desired electrical paths for the discrete components, clearances between the traces, and so forth. Ultimately, even a single SMT component within an integrated circuit package may introduce a technical challenge if it is important for the package to be compact, since these components require significant space on the substrate to be properly attached and connected. In cases where a plurality of discrete components is desired within a single package, the technical problem would be exacerbated even further.

Accordingly, as detailed herein, apparatuses and devices may use leadless discrete components in certain ways within the package to save space and provide other advantages described herein. For apparatuses described herein, leadless discrete components may be used (e.g., in place of SMT components and/or other components that include leads that must be accommodated in the ways described above) for at least one, and possibly for each, discrete component that may be included in a design of a particular integrated circuit component. As one example, for an integrated circuit component such as a power module, one or more semiconductor dies could be disposed on a substrate (e.g., a direct-bonded copper substrate, etc.) within the package and a discrete thermistor component may be integrated with the die on the same substrate to be embedded within the same package. For example, the discrete thermistor component may be used to help monitor temperature within the package.

Rather than using an SMT-style thermistor component with leads that have to be accommodated with pads, traces, and suitable clearances, apparatuses according to principles described herein would rely on a leadless thermistor component that can be conveniently and flexibly disposed in a variety of locations on the substrate and can be electrically connected using various approaches detailed below. For example, rather than needing pads and traces to accommodate both leads of the thermistor, a leadless thermistor component may be disposed on a single pad and electrically connected using a wire-based or clip-based conductor that takes up none of the substrate area. In some implementations, the leadless thermistor component could even be disposed and connected directly under a lead (i.e., sandwiched between the lead and the substrate) such that the component does not even require its own pad, thereby saving even more space on the substrate.

The technical effect of replacing SMT components with leadless discrete components according to this technical solution is that design constraints, particularly those related to substrate area, may be cased by the convenience and flexibility with which the discrete components may be placed in the design. More compact packages (e.g., in terms of both footprint and total area as well as in terms of profile and total volume of the package) may be made possible, which may in turn provide various technical and competitive advantages compared to packages that are less compact.

A second category of technical problems that may be addressed by use of leadless discrete components (and, in particular, by use of leadless temperature sensors such as leadless thermistors) relates to the challenge of measuring internal temperatures of an electronic component with high accuracy and timeliness.

For certain types of electronic components, it may be desirable for certain sensing technology to be incorporated into the chips (e.g., so that measurement data may be read out by one or more terminals of the component). For example, it may be beneficial for power electronics receiving and/or producing large amounts of current, as well as for other types of components that are especially temperature sensitive or tend to produce significant heat, to use a temperature sensing component to monitor the internal temperature of the electronic component. For example, by including a temperature sensor within the device package, a device within which the electronic component is used may conveniently determine and monitor the temperature of the component and implement thermal management strategies (e.g., to prevent overheating, to optimize performance, to detect potential faults or anomalies within the device, and so forth).

One technical problem that arises with internal temperature sensors integrated within a device package of an electronic component is that heat produced by one element within the package (e.g., a semiconductor die) takes time to spread to other parts of the package, such as to where the temperature sensor may be located. Another technical problem is that, even if the heat moved across the apparatus instantaneously, the heat gradually dissipates away from the heat source (e.g., with distance from the semiconductor die producing the heat) as energy spreads to other elements of the apparatus (including being intentionally drawn away by a heat sink integrated with the device package in some examples). Moreover, whatever heat does move from the heat source to other areas of the apparatus may not necessarily move uniformly, since some paths may include elements that tend to absorb and block heat transfer while other paths allow heat to travel more freely. Given all of these challenges, any temperature measured by a temperature sensor outside of a device package of an electronic component is likely to suffer from significant error and/or time delay, and even temperature measured directly inside the device package will suffer from these limitations to at least some extent.

Accordingly, leadless temperature sensors described herein can be used to provide at least one technical solution to all of these technical problems by allowing a leadless temperature sensor (e.g., a negative temperature coefficient (NTC) thermistor or the like) to be in direct contact with the semiconductor die to consistently determine highly accurate and timely measurements of the temperature of this heat source. For example, a leadless temperature sensor may be disposed directly on a pad of a semiconductor die in ways described herein. Various technical effects of this solution include that temperature may be measured without any thermal loss (or at least with far less thermal loss than may be measured by a temperature sensor that is not directly disposed on the semiconductor die). Along with being more accurate, the temperature measured may also suffer from less delay (i.e., be more timely) since an on-die leadless temperature sensor does not need to wait for heat to spread from the semiconductor die to other parts of the apparatus before being fully accounted for in measurements.

Moreover, in addition to these improvements in temperature sensing, another technical effect of using an on-die leadless temperature sensor is similar to technical effects described above for other types of leadless discrete components that are placed on dedicated pads or even sandwiched between the substrate and the lead. Specifically, using a leadless temperature sensor disposed on a semiconductor die, rather than taking up space on the substrate, can allow for more compact and efficient packaging (e.g., packaging with a smaller substrate, narrower leads, and a reduced component footprint, etc.). All of these benefits, in turn, may help optimize chip efficiency for electronic components utilizing these principles, and may ultimately help extend chip lifetimes (through effective temperature management), and increase design flexibility (through package size reduction).

Various implementations will now be described in more detail with reference to the figures. It will be understood that the particular implementations described below are provided as non-limiting examples and may be applied in various situations. Additionally, it will be understood that other implementations not explicitly described herein may also fall within the scope of the claims set forth below. Principles described herein for compact semiconductor packaging using leadless discrete components and for on-die temperature sensing using leadless temperature sensors within electronic components may result in any or all of the technical benefits mentioned above, as well as various additional technical benefits that will be described and/or made apparent below.

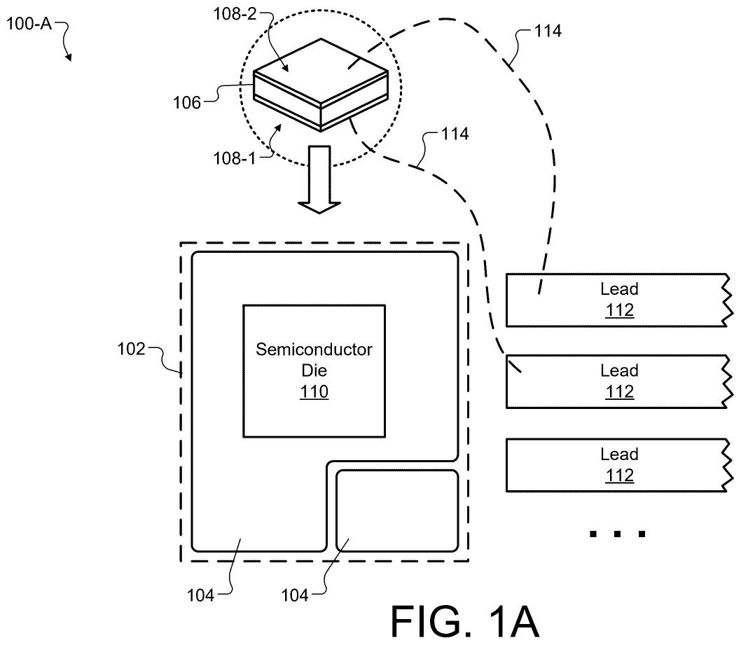

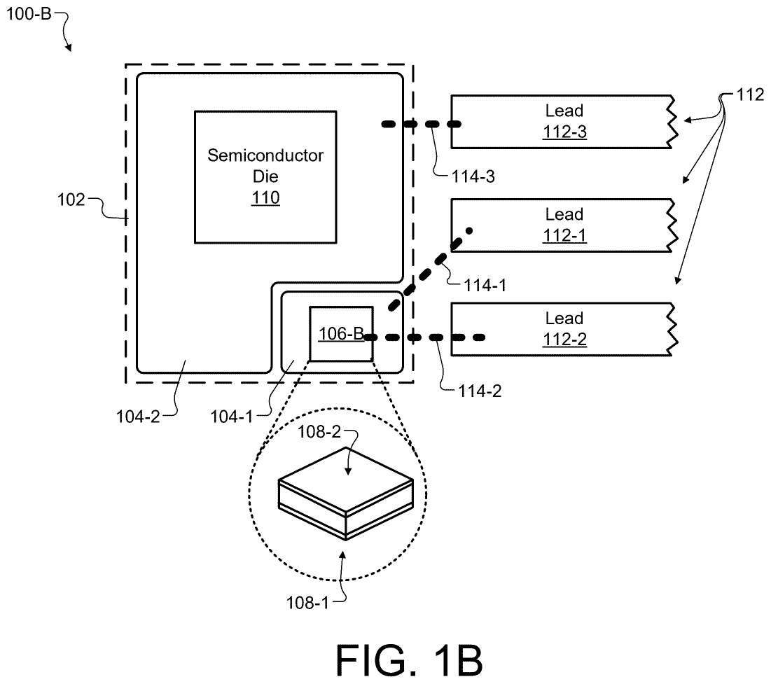

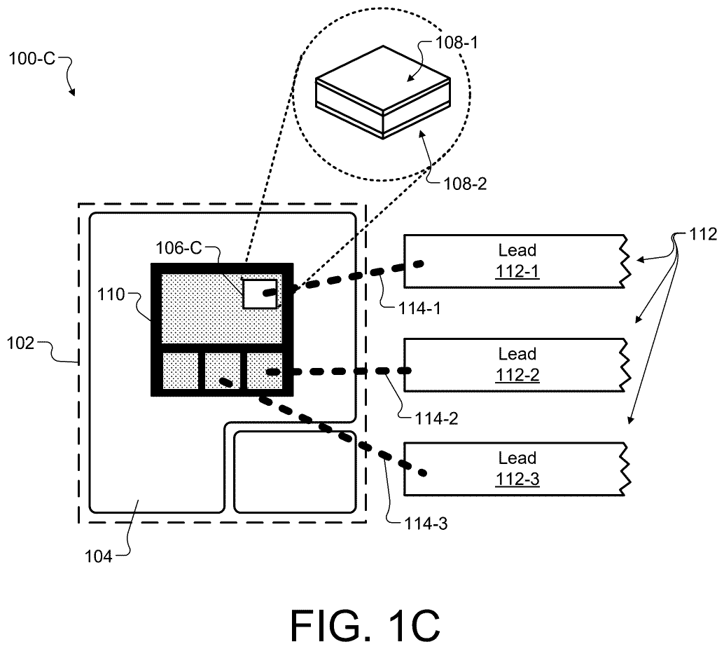

FIG. 1A shows illustrative elements of an apparatus 100-A (e.g., an electronic component such as a power inverter or the like) implementing temperature sensing using a leadless temperature sensor to be incorporated within a device package of the apparatus. As shown, apparatus 100-A includes a substrate 102 that may include multiple portions 104 that could be electrically isolated from one another (as well be described in more detail below). Somewhere within apparatus 100-A, a leadless temperature sensor 106 having a first surface 108-1 (e.g., a bottom surface) and a second surface 108-2 opposite the first surface (e.g., a top surface) may be integrated, along with a semiconductor die 110 disposed on the substrate 102 (e.g., disposed on one of portions 104, which are part of substrate 102) and implementing a transistor (e.g., a metal-oxide-semiconductor field effect transistor (MOSFET) or other suitable transistor). As will be described in more detail below, leadless temperature sensor 106 could be integrated within the device package on one of the portions 104 (e.g., the portion 104 isolated from the portion on which die 110 is disposed) or could be disposed directly on semiconductor die 110 itself. In either case, the leadless temperature sensor 106 may be configured to measure a temperature of semiconductor die 110.

Apparatus 100-A is further shown to include a plurality of leads 112 including at least a first lead and a second lead (in this case three leads are shown along with an ellipsis indicating that additional leads could also be included as may serve a particular implementation). A first lead 112 of the plurality of leads is shown to be electrically coupled with first surface 108-1 of leadless temperature sensor 106 by a first conductive component 114, while a second lead 112 of the plurality of leads is shown to be electrically coupled with second surface 108-2 of leadless temperature sensor 106 by a second conductive component 114. Conductive components 114 (also referred to as electrical connections) are shown in FIG. 1A as dotted lines to indicate that the conductive component extended between the two elements to form an electrical connection, but without indicating the precise nature of the conductive component or electrical connection. For example, as will be described and illustrated in various different examples below, electrical connections between these elements may be direct or indirect, and may use various types of conductive components (e.g., wirebonds, clips, joints, etc.).

As described above, different implementations of leadless discrete components such as the leadless temperature sensor 106 in FIG. 1A may be employed in different contexts for different apparatuses to achieve different goals. FIGS. 1B and 1C illustrate two such examples and correspond, respectively, to the technical solution categories described above of compact semiconductor packaging and on-die temperature sensing.

In the first example of FIG. 1B, illustrative elements of an apparatus 100-B are shown to implement compact semiconductor packaging using a leadless discrete component in accordance with principles described herein. In this example, substrate 102 is specifically shown to include a first portion 104-1 and a second portion 104-2 that are electrically isolated from one another. The leadless temperature sensor is implemented in this example as a more generic leadless discrete component 106-B that will be understood to represent either a temperature sensor or another suitable component (e.g., a discrete resistor, capacitor, inductor, diode, etc.).

Leadless discrete component 106-B is shown to be disposed on the first portion 104-1 while the semiconductor die 110 is shown to be disposed on the second portion 104-2. In this example, a first lead 112-1 of the plurality of leads 112 is shown to be electrically coupled with the first surface 108-1 of the leadless discrete component 106-B by way of an indirect electrical connection made by a conductive component 114-1 between lead 112-1 and portion 104-1 of substrate 102 (which will be understood to itself be electrically coupled with surface 108-1 of component 106-B). A second lead 112-2 of the plurality of leads 112 is then shown to be electrically coupled with the second surface 108-2 of the leadless discrete component 106-B by way of a direct electrical connection made by a conductive component 114-2 between lead 112-2 and surface 108-2 of component 106-B. Other leads 112 and corresponding electrical connections will be understood to be included in some implementations of the apparatus. For example, apparatus 100-B shows a lead 112-3 electrically connected to portion 104-2 of substrate 102 by way of a conductive component 114-3. Other electrical connections to other leads 112 not explicitly shown may also be included, as will be illustrated and described in more detail below.

Apparatus 100-B in FIG. 1B illustrates an implementation of packaging aspects for an apparatus that implements compact semiconductor packaging using a leadless discrete component in accordance with principles described herein. While this implementation does not depict all aspects that might be included in the apparatus (e.g., a completely packaged integrated circuit component), FIG. 1B illustrates certain principles for how such an apparatus may be constructed so as to be compact and provide other technical advantages described herein.

Apparatus 100-B represents a generalized implementation of an apparatus (e.g., an integrated circuit component packaged in accordance with principles described herein) from a top view, though it will be understood that various specific implementations of the apparatus in accordance with principles described and illustrated in relation to FIG. 1B may include various types of apparatuses used in various applications. As one particular example, the apparatus 100-B could represent an integrated circuit implementing a power module configured for use in an automotive application. In other examples, apparatus 100-B could represent other types of electronic components used for other types of applications. While various elements of apparatus 100-B are illustrated and described in relation to FIG. 1B, additional details and other optional elements, which will be understood to apply to this implementation and/or to other implementations of the apparatus, will be illustrated and described in relation to other figures below.

As shown and as introduced above, apparatus 100-B may include substrate 102 having first portion 104-1 and second portion 104-2 that is electrically isolated from the first portion. Substrate 102 may represent a directed-bonded metal (DBM) substrate such as a direct-bonded copper (DBC) substrate or the like that employs layers of a conductor (e.g., a metal such as copper, etc.) on an insulative tile (e.g., a ceramic plate, etc.) to facilitate electrical insulation between different the different portions 104-1 and 104-2, to distribute signals to various places (e.g., using signal traces, power or ground planes, etc.), to provide thermal management for the apparatus (e.g., due to high thermal conductivity of the conductor, which helps to dissipate heat), and so forth. As one example, substrate 102 may include a ceramic plate having a first side and a second side opposite the first side. The first side of the ceramic plate may be direct-bonded to a first metal layer (visible from the view of FIG. 1B) that is patterned to include various different portions including portions 104-1 and 104-2. The second side of the ceramic plate (not shown in FIG. 1B) may then be direct-bonded to a second metal layer that is configured to facilitate heat transfer away from the apparatus (e.g., acting as a heat sink to dissipate heat from heat-generating elements of the apparatus that will be described below). In other examples of substrate 102, both the first side and the second side may be patterned to include various portions (e.g., traces, planes, etc.) or both sides may include a solid plan of metal without any such electrically isolated portions. Moreover, it will be understood that both sides of the substrate may help dissipate heat.

A DBM-based implementation of substrate 102 may offer various advantages for the packaging of apparatuses such as described herein. For example, this type of substrate 102 may be configured to handle relatively large currents and voltages due to efficient thermal management provided by the heat dissipation mentioned above. This may be useful for apparatuses such as power modules that generate and/or consume large amounts of power. For instance, apparatuses described herein could implement AC/DC converter modules configured to convert alternating current (AC) to direct current (DC) for computer power supplies or the like, DC/AC converter modules configured to convert DC to AC for regulating automotive electrical systems or the like, inverters for use in power systems or electric vehicles, motor drives used for appliances or electric vehicles, and various other examples as may serve a particular implementation. Other example advantages that DBM-based implementations of substrate 102 may offer include improved reliability (since the direct-bonding process between the ceramic and metal layers may create a strong and reliable connection), reduced size and weight (since DBM substrates are relatively thin and lightweight compared to other packaging materials), and so forth.

Despite the advantages of DBM and other similar substrates described herein, it will be understood that substrate 102 may additionally or alternatively be implemented in other ways. For example, a leadframe constructed of copper or another suitable material may be formed with the pattern shown in FIG. 1B (e.g., with portions 104-1 and 104-2, etc.), and the direct-bonded layers of metal and ceramic described above may not be used. As used herein, a leadframe may refer to conductive portions of a device package (e.g., conductive leads, terminals, etc.) that are configured to provide external connection points for the package. For example, wirebonds, clips, or other electrical connections may be used to couple individual leads of the leadframe to circuitry within the device package (e.g., a substrate, a semiconductor die, etc.) and these leads may extend from the device package (e.g., emerging from the molding material) to connect to external circuitry an any suitable way, such as by being soldered or otherwise coupled to a circuit board. Accordingly, the leadframe can be referred to as a conductive portion or a metal portion of the device package. In some implementations, one or more portions of a leadframe can be coupled to a pad (e.g., a bond pad) on at least a portion of a DBM substrate.

Regardless of how substrate 102 is implemented, FIG. 1B shows that portion 104-1 may be electrically isolated from portion 104-2. For example, the shapes labeled as portions 104-1 and 104-2 may be understood to represent separate planes of direct-bonded metal on a ceramic tile (not explicitly shown) or to represent separate parts of a leadframe (which may be held together during the manufacturing process by tie bars or other such mechanisms that would later be removed and are not explicitly shown in FIG. 1B). Additionally, while not shown in this example, it will be understood that additional portions of substrate 102 may also be included to implement pads for components, traces, and so forth.

As further shown in apparatus 100-B, leadless discrete component 106-B (abbreviated as “LDC” in certain figures herein) is shown in three-dimensional closeup (in the dotted circle expansion extending out of leadless discrete component 106-B) to have first surface 108-1 and second surface 108-2 opposite first surface 108-1. First surface 108-1 will be understood to be both physically coupled and electrically coupled to first portion 104-1 of substrate 102, as shown. In other words, first surface 108-1 may represent the bottom of leadless discrete component 106-B in this configuration, which may be soldered, sintered, attached by an adhesive, or otherwise physically and electrically coupled to portion 104-1. Meanwhile, second surface 108-2 may represent the top of the leadless discrete component 106-B in this configuration, which is isolated from first surface 108-1 and from portion 104-1 but may be connected in other possible ways with other elements as will be detailed below.

Leadless discrete component 106-B may be referred to by other names (e.g., a bondable component, etc.) and may be distinguished from discrete components packaged using surface mount technology (SMT) by the absence of leads on the component and the way that terminals of the component, implemented by conductive surfaces 108-1 and 108-2, may be electrically connected to other conductors. As will be made apparent with various examples described below, the leadless form factor of leadless discrete component 106-B may allow for significant flexibility in how the component is physically and electrically coupled to other elements of the apparatus. For example, a top-side termination (e.g., constructed from a nickel-gold alloy or the like) may be well-suited for direct aluminum wire bonding or other suitable connection techniques. A bottom-side termination of leadless discrete component 106-B may be well-suited for various mechanisms whereby the component is both physically and electrically coupled to a conductive surface below it (e.g., by way of soldering, silver sintering, conductive adhesion, etc.).

While the leadless temperature sensor 106 described in relation to apparatus 100-A was described specifically as a leadless temperature sensor configured to measure a temperature of die 110, leadless discrete component 106-B may represent any type of discrete electronic component as may serve a particular implementation (since the primary objective of apparatus 100-B is to provide compact semiconductor packaging by using leadless discrete components in place of any surface mount devices). In particular, it will be understood that leadless discrete component 106-B may be any component selected to serve a particular purpose in the final function of the apparatus. As a first example, leadless discrete component 106-B may be implemented as a leadless temperature sensor (e.g., a thermistor component) configured for detecting a temperature within apparatus 100-B during operation of the apparatus. For instance, if apparatus 100-B is a power module or other such integrated circuit, it may be useful to monitor the temperature of the module by using a thermistor that is embedded directly in the module near the die. As another example, leadless discrete component 106-B may be implemented as one of a resistor component configured to resist a current for a circuit of the apparatus during operation of the apparatus or a capacitor component configured to store an electrical charge for the circuit of the apparatus during the operation of the apparatus. In either of these cases, the leadless discrete component may interoperate with other circuitry within the apparatus, such as by being connected with the die in a certain configuration to implement a particular circuit with desirable functionality. In still other examples, leadless discrete component 106-B could be implemented as another type of discrete component such as an inductor, a diode, or the like.

Similar to the coupling between leadless discrete component 106-B and portion 104-1 of substrate 102, semiconductor die 110 is shown to be physically coupled and electrically coupled to portion 104-2 of substrate 102. Semiconductor die 110 may represent any suitable semiconductor die as may serve a particular implementation. For instance, semiconductor die 110 may implement a single transistor (e.g., a power transistor, etc.) or a circuit with a plurality of transistors. While only one die 110 is shown in the example of FIG. 1B, it will be understood that certain apparatuses may be packaged with a plurality of dies in the same package. This is similar to the way that there could also be a plurality of discrete components (e.g., leadless discrete components, SMT components, a combination of both, etc.). In some cases, a single package of an integrated circuit component may include hybrid dies constructed from different semiconductor materials and/or using different fabrication processes or technologies. For example, hybrid dies may exhibit different properties, operate within different parameter ranges (e.g., a lower voltage die and a higher voltage die, etc.), and/or have other distinct traits that serve other purposes. In one example of a component with hybrid dies, a first die (e.g., die 110) could be fabricated on a silicon (Si) substrate, while a second die (not shown in FIG. 1B) could be fabricated on a substrate of another suitable semiconductor material such as silicon carbide (SIC).

FIG. 1B also shows that apparatus 100-B may include the plurality of leads 112 (understood to each be shown only in part, as illustrated by the jagged cutoff representing the remainder of the leads that is not explicitly depicted). The plurality of leads 112 is shown to include first lead 112-1 electrically coupled to portion 104-1 of substrate 102, second lead 112-2 electrically coupled to second surface 108-2 of leadless discrete component 106-B, and third lead 112-3 electrically coupled to portion 104-2 of substrate 102. To illustrate these electrical couplings, FIG. 1B shows dashed lines representing conductive component 114-1 (coupled to lead 112-1 and to portion 104-1 of substrate 102), conductive component 114-2 (coupled to lead 112-2 and to surface 108-2 of leadless discrete component 106-B), and conductive component 114-3 (coupled to lead 112-3 and to portion 104-2 of substrate 102). While only three conductive components 114-1 through 114-3 are explicitly shown in this example, it will be understood that other conductive components between various elements of the apparatus could also be included in certain implementations. A few examples of such conductive components could include, without limitation, a conductive component coupled to die 110 and to another lead; a conductive component coupled to die 110 and to leadless discrete component 106-B; a conductive component coupled to either die 110 or leadless discrete component 106-B, and to one of the following: another semiconductor die (not depicted), another discrete component (not depicted), a particular portion of substrate 102 (e.g., one of portions 104-1 or 104-2 or another portion not depicted), another lead, or the like.

Conductive components 114-1 through 114-3 may each be implemented in any manner as may serve a particular implementation. For instance, in some examples, these conductive components could represent wires coupled to their respective elements by way of a wire bonding process or other suitable technique. In other examples, the conductive components could represent clips that electrically connect the elements shown. In still other examples, the conductive components could represent direct physical and electrical connections whereby the elements are physically attached to one another by way of a connection mechanism that provides the electrical connections (e.g., solder material, sintering material, conductive adhesive, etc.). In some cases, a combination of different types of conductive components may be employed within the same package or within the same implementation. For instance, certain connections could use wire bonding while other connections could utilize clips or direct connections. Each of these types of connections will be described and illustrated in more detail below with respect to specific implementations of apparatus 100-B of FIG. 1B.

Turning to the second technical solution category (on-die temperature sensing) illustrated by the example of FIG. 1C, illustrative elements of an apparatus 100-C are shown to implement on-die temperature sensing within the apparatus (e.g., any of the types of packaged electronic components described herein). In this example, apparatus 100-C is shown to include a substrate 102 implemented in any of the ways described above (e.g., as a DBM substrate, as a leadframe, etc.). A semiconductor die 110 is again shown to be disposed on the substrate, this semiconductor die 110 implementing a transistor and including several pads (illustrated as gray boxes on the otherwise black die) on a surface of the semiconductor die 110 facing away from the substrate (i.e., facing up). An example layout of these pads will be described in more detail below, but it will be understood that certain pads may be associated with separate circuit nodes within the die (e.g., a source pad associated with a source of the transistor and a gate pad associated with a gate of the transistor), while other pads may be internally coupled to the same or a related node (e.g., the source pad and a Kelvin sense pad used to accurately measure voltage or current at the source of the transistor).

A leadless temperature sensor 106-C is shown to be disposed on one of the pads of the semiconductor die 110 (i.e., a pad on a die surface facing away from substrate 102, as shown). To illustrate that certain leadless temperature sensors (as with other leadless discrete components described herein) may be bidirectional (i.e., equally functional regardless of which direction current flows through them), leadless temperature sensor 106-C is shown to be flipped from examples above, such that first surface 108-1 is now on top while second surface 108-2 is now on bottom. Accordingly, as shown, second surface 108-2 of leadless temperature sensor 106-C may be physically coupled to the pad of semiconductor die 110 while first surface 108-1 is facing up (away from semiconductor die 110). While certain discrete components may be bidirectional in this way, it will be understood that others are not bidirectional. For example, certain leadless temperature sensors could define an output termination (e.g., the first or top surface 108-1) and an input termination (e.g., the second or bottom surface 108-2), rather than these terminations being interchangeable.

A plurality of leads 112 is again shown with several specific leads 112-1, 112-2, and 112-3 being electrically coupled to various elements by way of respective electrical connections made by conductive components 114-1, 114-2, and 114-3. More particularly, a first lead 112-1 is shown to be electrically coupled, by way of a conductive component 114-1, with the first (top) surface 108-1 of leadless temperature sensor 106-C (i.e., the surface facing away from the surface of the semiconductor die). A second lead 112-2 is shown to be electrically coupled, by way of a conductive component 114-2, with the surface of the semiconductor die 110.

In this example of apparatus 100-C (and in contrast to the polarity of the discrete component in apparatus 100-B), first lead 112-1 is shown to be directly electrically coupled with first surface 108-1 of leadless temperature sensor 106-C while second lead 112-2 is shown to be indirectly electrically coupled with second surface 108-2 of leadless temperature sensor 106-C by being coupled to the surface of the semiconductor die 110. This is analogous to the electrical connection described above in relation to FIG. 1B, where lead 112-1 was connected to surface 108-1 indirectly by being coupled to the portion 104-1 of the substrate 102 on which the leadless discrete component 106-B was disposed. In this case, however, a direct electrical connection made by conductive component 114-2 is shown to be coupled to the surface of the semiconductor die 110 not on the same pad as leadless temperature sensor 106-C is disposed (though that may also be performed in certain implementations), but on a different pad that will be understood to itself be electrically coupled to the pad on which leadless temperature sensor 106-C is disposed. For example, as will be described in more detail below, leadless temperature sensor 106-C may be disposed on a source pad of the semiconductor die 110, while the direct electrical connection of conductive component 114-2 may be to a Kelvin sense pad that is internally coupled with the source pad.

A third lead 112-3 is also shown to be electrically coupled, by way of an electrical connection provided by a conductive component 114-3 with the surface of the semiconductor die 110 at yet another pad. For example, as will be described in more detail below, this connection may be to a gate pad that is not coupled with the source pad and the Kelvin sense pad.

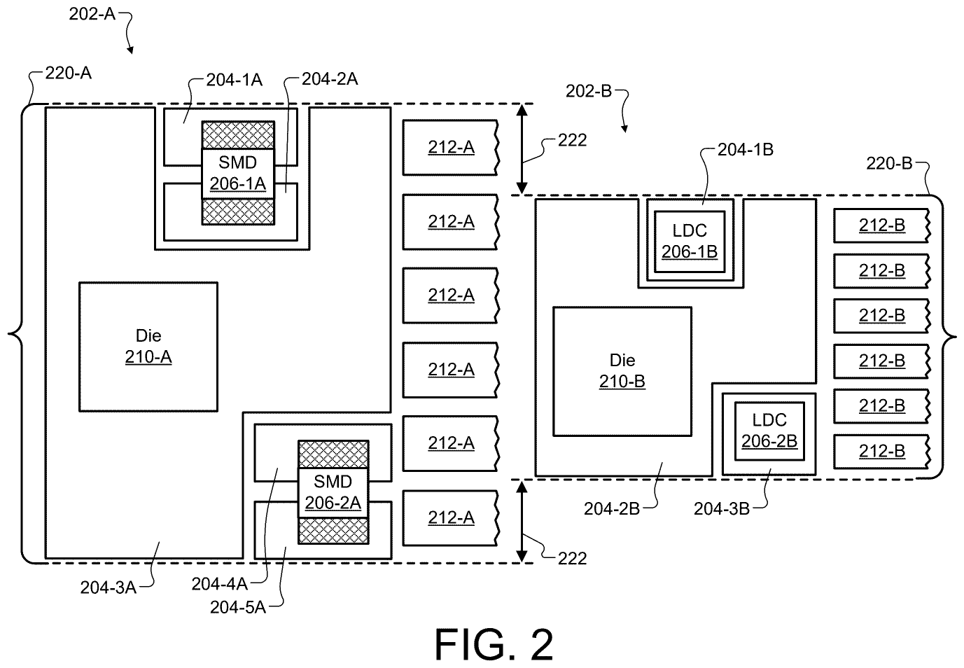

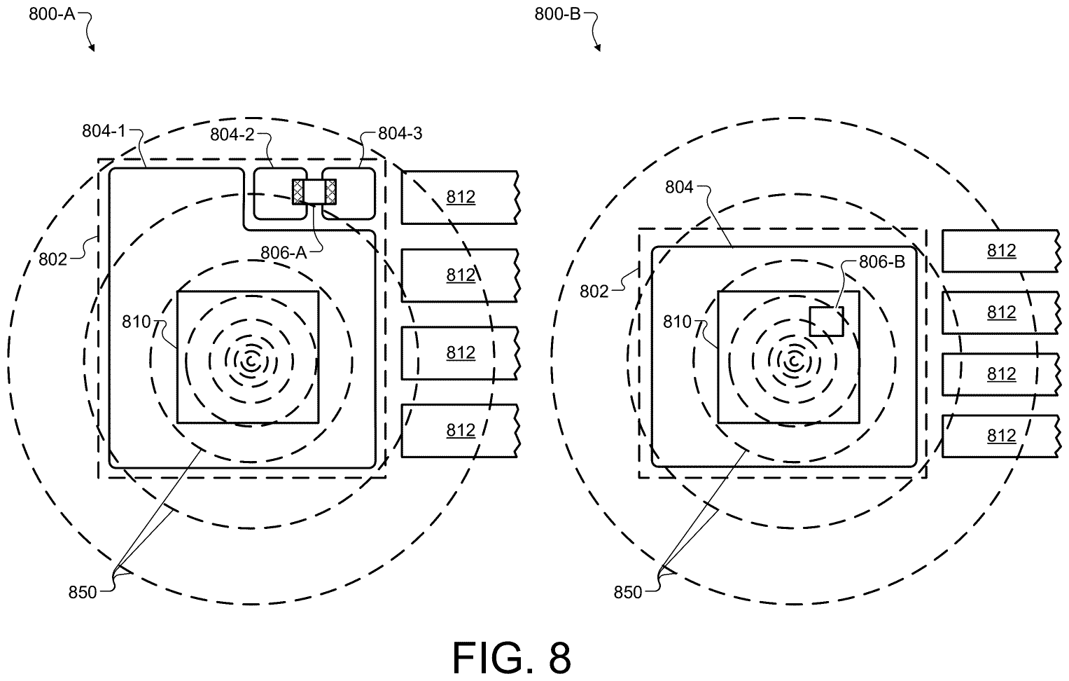

Having introduced certain general concepts in relation to FIG. 1A (apparatus 100-A), certain compact semiconductor packaging concepts in relation to FIG. 1B (apparatus 100-B), and certain on-die temperature sensing concepts in relation to FIG. 1C (apparatus 100-C), additional detail regarding how leadless components may be used will now be provided. More specifically, additional detail regarding compact semiconductor packaging using leadless discrete components will now be described in relation to FIGS. 2, 3A-3D, 4A-4D, 5A-5D, 6, and 7, followed by additional detail regarding on-die temperature sensing within electronic components using leadless temperature sensors, which will be described in relation to FIGS. 8, 9A-9B, 10-12, and 13A-13B.

FIG. 2 contrasts illustrative aspects of conventional semiconductor packaging with compact semiconductor packaging using leadless discrete components in accordance with principles described herein. More particularly, as shown, various elements (each ending with ‘A’ designations) are shown on the left-hand side of FIG. 2 to illustrate aspects of conventional semiconductor packaging and to contrast these with like-numbered elements (each ending with ‘B’ designations) on the right-hand side of FIG. 2 to illustrate aspects of compact semiconductor packaging in accordance with principles described herein. Reference numbers in FIG. 2 that correspond to components described in relation to FIGS. 1A-1C are similar to the corresponding reference numbers in FIGS. 1A-1C, though they begin with ‘2’ rather than ‘1’. For example, substrate 102 was described in relation to FIGS. 1A-1C, so FIG. 2 shows a corresponding substrate 202-A (for the conventional example) and a corresponding substrate 202-B (for the compact example). Similarly, since substrate 102 in apparatuses 100-A to 100-C was shown to include portions 104 (and portions 104-1 and 104-2 in apparatus 100-B), substrate 202-A in FIG. 2 is shown to include various portions referred to as portions 204-A (including portions 204-1A, 204-2A, 204-3A, 204-4A, and 204-5A), while substrate 202-B in FIG. 2 is shown to include various portions referred to as portions 204-B (including portions 204-1B, 204-2B, and 204-3B).

While a single leadless discrete component 106-B (which, as described, could be implemented by a leadless temperature sensor or other suitable leadless component) was illustrated and described in relation to FIG. 1B, both example apparatuses in FIG. 2 are shown to include two discrete components to illustrate how the advantages of compact packaging described herein may increase the more discrete components are used.

Turning first to the conventional apparatus, FIG. 2 shows that, in place of a leadless discrete component, the conventional apparatus in FIG. 2 includes a surface mount device 206-1A and a surface mount device 206-2A (both labeled “SMD” in the figure due to space constraints). As shown, and in contrast to leadless discrete component 106-B in FIG. 1B, each of the surface mount devices 206-1A and 206-2A is implemented by a discrete component with an SMT-style form factor. As such, these surface mount devices each include leads (the rectangles filled in with cross hatching) that are connected to individual portions of substrate 202-A that are carved out (with sufficient clearances, etc., to avoid circuit shorts) specifically for this purpose. More particularly, as shown, surface mount device 206-1A spans portions 204-1A and 204-2A of substrate 202-A while surface mount device 206-2A spans portions 204-4A and 204-5A of substrate 202-A. Moreover, just as semiconductor die 110 was disposed on portion 104-2 of substrate 102 in FIG. 1B, FIG. 2 shows a die 210-A disposed on portion 204-3A of substrate 202-A. While specific electrical connections are not shown in FIG. 2, a plurality of leads 212-A corresponding to leads 112 in FIG. 1B is also shown and will be understood to be configured to be electrically connected with various elements of the apparatus in accordance with principles that have been described.

FIG. 2 also shows various components of the compact apparatus to contrast the conventional apparatus. Specifically, in place of the leadless discrete component 106-B described above (and instead of surface mount devices 206-1A and 206-2A), the compact apparatus in FIG. 2 is shown to include a leadless discrete component 206-1B and a leadless discrete component 206-2B (both abbreviated as “LDC” in the figure). These leadless discrete components have the same leadless form factor described above for leadless discrete component 106-B (as well as leadless temperature sensors 106-A and 106-C) and, as such, are shown to be disposed on respective portions 204-1B and 204-2B of corresponding substrate 202-B without the need for additional portions and clearances like those needed for the leads of surface mount devices 206-1A and 206-2A. A die 210-B is shown to be disposed on portion 204-2B of substrate 202-B and a plurality of leads 212-B (corresponding to leads 112 in FIG. 1A and leads 212-A in the conventional apparatus) is shown next to corresponding substrate 202-B. It will be understood that these leads may be electrically connected with various elements of the apparatus in accordance with principles that have been described.

Having introduced the various components of the two contrasting apparatuses in FIG. 2, attention will now be drawn to certain differences in the characteristics of the apparatuses to illustrate certain space saving advantages that leadless discrete components may help provide. Specifically, the conventional apparatus on the left is shown to have a width 220-A that is considerably larger than a width 220-B of the compact apparatus on the right. Dashed lines are drawn along both of these widths to show a compactization 222 representing a difference between widths 220-A and 220-B. As illustrated by compactization 222, the implementation of the apparatus employing the leadless discrete components may include all the same circuitry and functionality (with an identically sized die in the package) while supporting a smaller footprint for the apparatus. As has been mentioned, smaller substrates and overall package sizes may provide various advantages. Besides saving costs, these compact packages may also fit more easily and flexibly in more places (thereby facilitating design of circuits or devices that use the integrated circuit components implemented by these apparatuses). Smaller package sizes may also lead to improved cooling possibilities, reduced power, and other advantages.

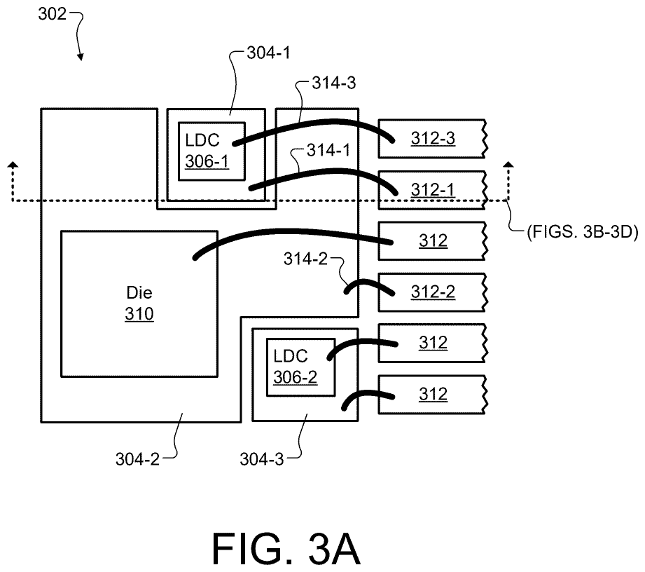

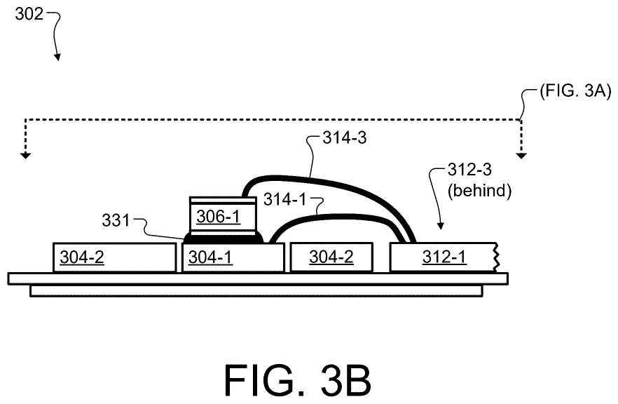

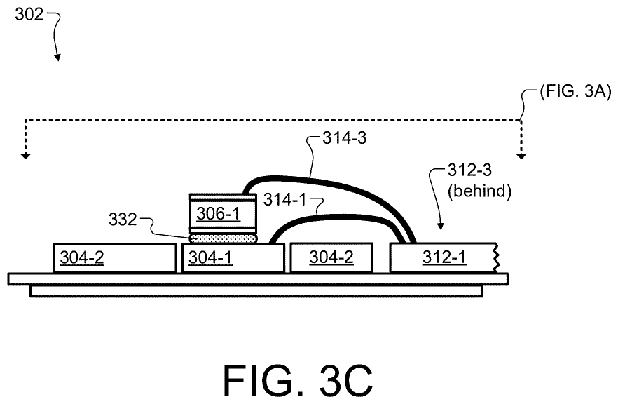

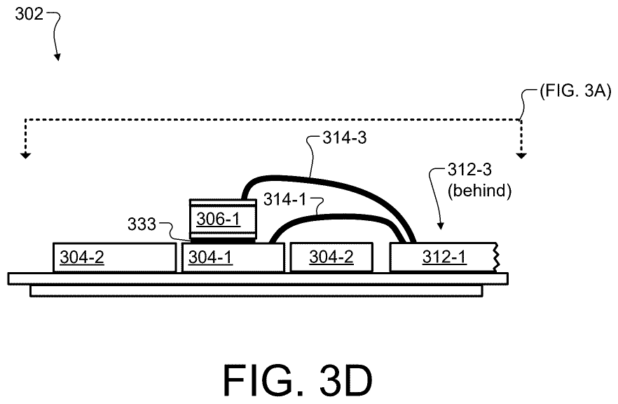

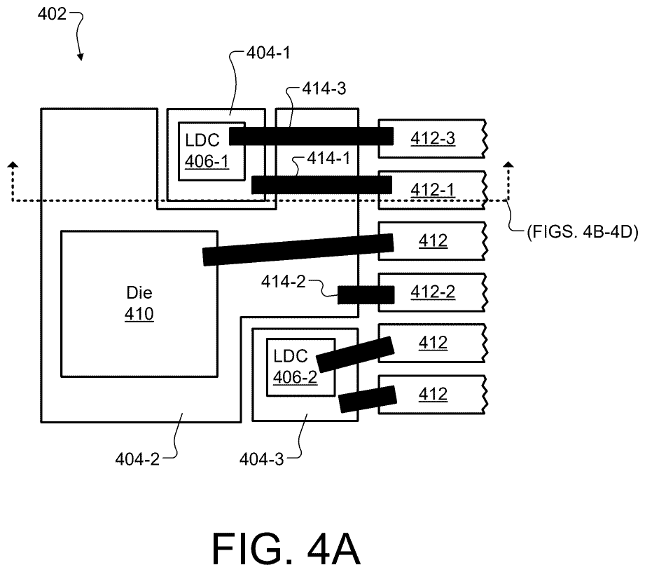

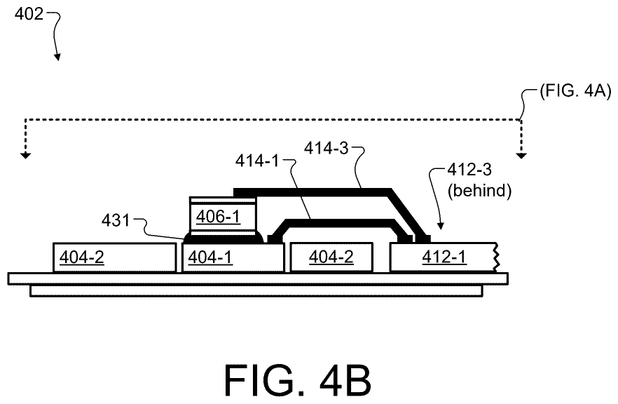

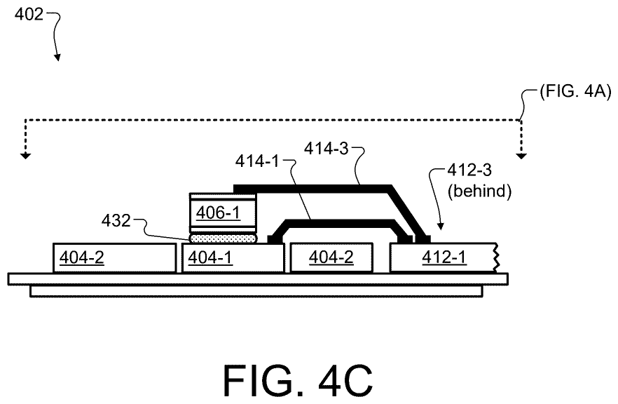

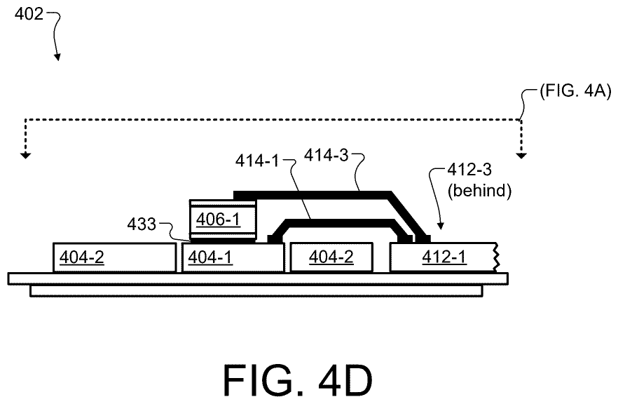

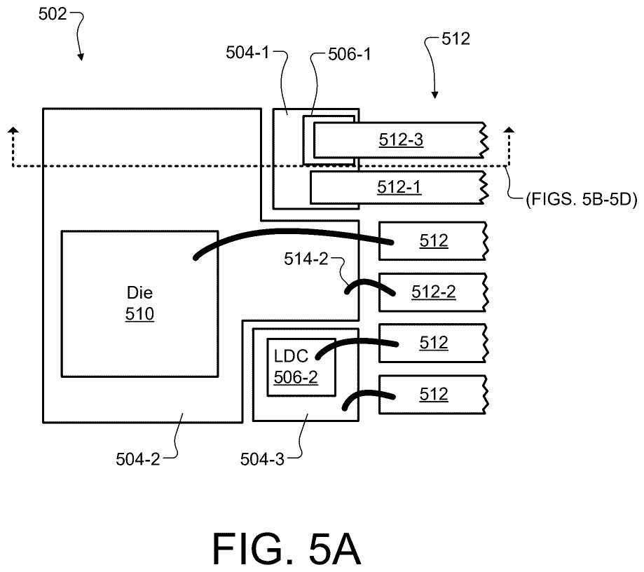

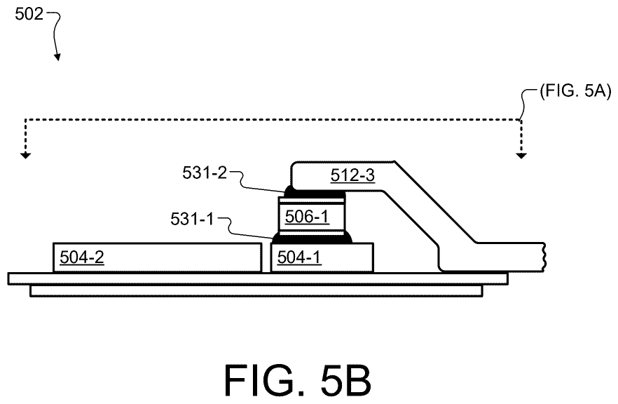

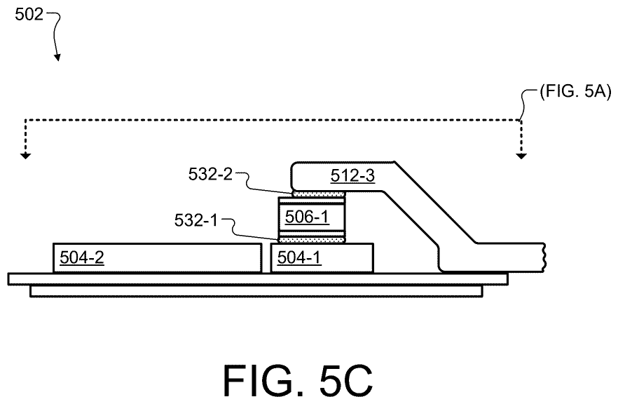

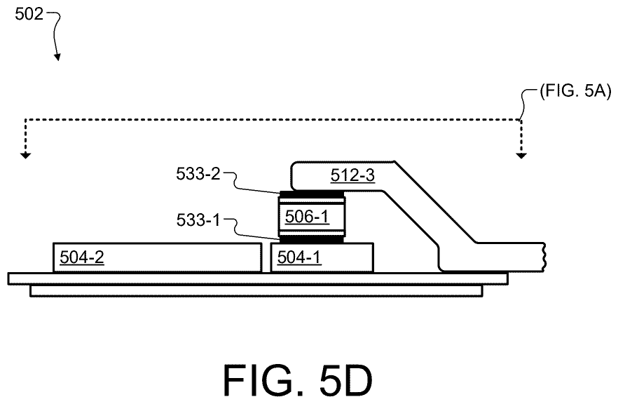

A variety of implementations of apparatuses in accordance with principles described herein will now be described in relation to FIGS. 3A-5D. Specifically, implementations in which a leadless discrete component is coupled via wire bonding will be illustrated and described in relation to FIGS. 3A-3D. Implementations in which a leadless discrete component is coupled via clips will be illustrated and described in relation to FIGS. 4A-4D. Implementations in which a leadless discrete component is coupled directly (e.g., by being disposed under a lead between the lead and the substrate) will be illustrated and described in relation to FIGS. 5A-5D. In each of these sets of examples, a first figure (i.e., FIGS. 3A, 4A, and 5A) shows an implementation of the apparatus similar to the compact apparatus shown in FIG. 2 and including corresponding numbering schemes (though the first digit is updated for each of these figures from the ‘2’ of FIG. 2 to ‘3’, ‘4’, or ‘5’ to match the respective figure number). The other figures in each of these sets of examples show implementations from a cross-sectional side view and likewise use the same numbering schemes.

FIG. 3A shows illustrative aspects of compact semiconductor packaging using a leadless discrete component and wire-based electrical couplings in accordance with principles described herein. Specifically, as mentioned, similar elements as have already been described are shown to make up the apparatus of FIG. 3A, including a substrate 302 having a first portion 304-1, a second portion 304-2, and a third portion 304-3. Two leadless discrete components (both abbreviated as “LDC” in the figure) are disposed on this substrate, including a leadless discrete component 306-1 that is physically and electrically coupled to first portion 304-1 and a leadless discrete component 306-2 that is physically and electrically coupled to second portion 304-3. While not explicitly labeled in FIG. 3A, each of these leadless discrete components 306-1 and 306-2 will be understood to terminate in opposing surfaces corresponding to surfaces 108-1 and 108-2 described above. A die 310 is shown to be physically and electrically coupled to second portion 304-2 of substrate 302, and a plurality of leads 312 are shown to connect to various elements of the apparatus by way of conductive components that would be analogous to conductive components 114-1 through 114-3 in FIGS. 1A-IC.

In the implementations of FIGS. 3A-3D, the conductive components are shown to be implemented by wires coupled to the various elements using a wire bonding technique. Various wires are not explicitly labeled in FIG. 3A, and it will be understood that the connections made by these wires are illustrative and could be different for other implementations. Three specific wires that are labeled, however, include a wire 314-1 that electrically couples a lead 312-1 and portion 304-1, a wire 314-2 that electrically couples a lead 312-2 and portion 304-2, and a wire 314-3 that electrically couples a lead 312-3 and a top surface of leadless discrete component 306-1. In this example, leadless discrete component 306-2 and die 310 are shown to be similarly connected by other (unlabeled) wires to other leads 312. A dotted line indicator labeled “FIGS. 3B-3D” is included within FIG. 3A to contextualize cross-sectional views that are depicted in each of FIGS. 3B-3D.

Accordingly, FIG. 3B shows, in a cross-sectional side view (similarly contextualized by a dotted line indicator labeled “FIG. 3A”), illustrative aspects of a solder-based implementation of the compact semiconductor packaging of FIG. 3A in accordance with principles described herein. Specifically, as shown from this side view, wire 314-1 couples portion 304-1 of substrate 302 to lead 312-1, while wire 314-3 couples the top surface of leadless discrete component 306-1 to lead 312-3 (labeled but not explicitly depicted from this view since it is behind lead 312-1). Each of these wires is shown to pass over portion 304-2 of substrate 302 so as to avoid electrically connecting leadless discrete component 306-1 to that portion (and thereby to the die). Rather, any desired connections to die 310 could be made by other conductive components (wires, etc.) as may serve a particular implementation (not shown).

In FIG. 3B, the first (bottom) surface of leadless discrete component 306-1 is shown to be physically coupled and electrically coupled to portion 304-1 of substrate 302 via a solder material 331. For example, in this implementation, leadless discrete component 306-1 may be soldered into place on portion 304-1 during the manufacturing process in any suitable manner. As a consequence of solder material 331, leadless discrete component 306-1 is not only physically coupled to portion 304-1 but also electrically coupled, such that current may flow between the first surface of the leadless discrete component, the solder, portion 304-1, wire 314-1, and lead 312-1. In other words, all of these elements will be understood to be on a same circuit node, just as the second (top) surface of leadless discrete component 306-1 is on a circuit node that includes wire 314-3 and lead 312-3.

FIG. 3C shows a similar cross-sectional view as FIG. 3B, except that, instead of a solder-based implementation, FIG. 3C shows a sinter-based implementation. Specifically, as shown, a sintering material 332 replaces solder material 331 to physically and electrically couple the first (bottom) surface of leadless discrete component 306-1 to portion 304-1 of substrate 302. For example, in this implementation, leadless discrete component 306-1 may be placed with the sintering material 332 (e.g., a fine or granular powder composed of conductive material such as silver, gold, copper, nickel alloy, etc.) between the bottom surface and portion 304-1 of substrate 302. Then, as part of the manufacturing process, a sintering operation (e.g., within a pressure chamber, etc.) may be performed to complete the sintering connection between the component and the substrate.

Similarly, FIG. 3D shows a similar cross-sectional view as FIGS. 3B and 3C, except that, instead of a solder-based implementation or a sinter-based implementation, FIG. 3D shows an adhesive-based implementation. Specifically, as shown, a conductive adhesive material 333 is used to physically and electrically couple the first (bottom) surface of leadless discrete component 306-1 to portion 304-1 of substrate 302. For example, in this implementation, leadless discrete component 306-1 may be placed with the conductive adhesive material 333 between the bottom surface and portion 304-1. In some examples, the conductive adhesive may cure or otherwise solidify as part of the manufacturing process. In any event, conductive adhesive material 333 may ultimately function to physically and electrically couple leadless discrete component 306-1 to first portion 304-1 in a similar manner as solder material 331 and/or sintering material 332.

In each of the cross-sectional side views of FIGS. 3B-3D, substrate 302 is shown to include not only the patterned top metal surface (including portions 304-1 and 304-2) but also two additional layers representing, for example, a ceramic (or other non-conductive) tile on which the patterned metal surface is disposed, and a bottom metal surface (e.g., direct bonded copper, etc.) that may function to dissipate heat and/or provide other advantages as described above. It will be understood that these layers may be implemented in different ways or could be omitted in certain examples as may serve a particular implementation.

FIG. 4A shows illustrative aspects of compact semiconductor packaging using a leadless discrete component and clip-based electrical couplings in accordance with principles described herein. Specifically, as mentioned, similar elements as have already been described are shown to make up the apparatus of FIG. 4A, including a substrate 402 having a first portion 404-1, a second portion 404-2, and a third portion 404-3. Two leadless discrete components (both abbreviated as “LDC” in the figure) are disposed on this substrate, including a leadless discrete component 406-1 that is physically and electrically coupled to first portion 404-1 and a leadless discrete component 406-2 that is physically and electrically coupled to second portion 404-3. While not explicitly labeled in FIG. 4A, each of these leadless discrete components 406-1 and 406-2 will be understood to terminate in opposing surfaces corresponding to surfaces 108-1 and 108-2 described above. A die 410 is shown to be physically and electrically coupled to second portion 404-2 of substrate 402, and a plurality of leads 412 are shown to connect to various elements of the apparatus by way of conductive components (analogous to conductive components 114-1 through 114-3 in FIGS. 1A-1C).

In the implementations of FIGS. 4A-4D, the conductive components are shown to be implemented by clips coupled to the various elements. Various clips are not explicitly labeled in FIG. 4A, and it will be understood that the connections made by these clips are illustrative and could be different for other implementations. Three specific clips that are labeled, however, include a clip 414-1 that electrically couples a lead 412-1 and first portion 404-1, a clip 414-2 that electrically couples a lead 412-2 and portion 404-2, and a clip 414-3 that electrically couples a lead 412-3 and a top surface of leadless discrete component 406-1. In this example, leadless discrete component 406-2 and die 410 are shown to be similarly connected by other (unlabeled) clips to other leads 412. A dotted line indicator labeled “FIGS. 4B-4D” is included within FIG. 4A to contextualize cross-sectional views that are depicted in each of FIGS. 4B-4D.

Accordingly, FIG. 4B shows, in a cross-sectional side view (similarly contextualized by a dotted line indicator labeled “FIG. 4A”), illustrative aspects of a solder-based implementation of the compact semiconductor packaging of FIG. 4A in accordance with principles described herein. Specifically, as shown from this side view, clip 414-1 couples portion 404-1 of substrate 402 to lead 412-1, while clip 414-3 couples the top surface of leadless discrete component 406-1 to lead 412-3 (labeled but not explicitly depicted from this view since it is behind lead 412-1). Each of these clips is shown to pass over portion 404-2 of substrate 402 so as to avoid electrically connecting leadless discrete component 406-1 to that portion (and thereby to the die). Rather, any desired connections to die 410 could be made by other conductive components (clips, wires, etc.) as may serve a particular implementation (not shown).

In FIG. 4B, the first (bottom) surface of leadless discrete component 406-1 is shown to be physically coupled and electrically coupled to portion 404-1 of substrate 402 via a solder material 431. For example, in this implementation, leadless discrete component 406-1 may be soldered into place on portion 404-1 during the manufacturing process in any suitable manner. As a consequence of solder material 431, leadless discrete component 406-1 is not only physically coupled to portion 404-1 but also electrically coupled, such that current may flow between the first surface of the leadless discrete component, the solder, portion 404-1, clip 414-1, and lead 412-1. In other words, all of these elements will be understood to be on a same circuit node, just as the second (top) surface of leadless discrete component 406-1 is on a circuit node that includes clip 414-3 and lead 412-3.

FIG. 4C shows a similar cross-sectional view as FIG. 4B, except that, instead of a solder-based implementation, FIG. 4C shows a sinter-based implementation. Specifically, as shown, a sintering material 432 replaces solder material 431 to physically and electrically couple the first (bottom) surface of leadless discrete component 406-1 to portion 404-1 of substrate 402. For example, in this implementation, leadless discrete component 406-1 may be placed with the sintering material 432 (e.g., silver sinter, etc.) between the bottom surface and portion 404-1 of substrate 402. Then, as part of the manufacturing process, a sintering operation (e.g., within a pressure chamber, etc.) may be performed to complete the sintering connection between the component and the substrate.

Similarly, FIG. 4D shows a similar cross-sectional view as FIGS. 4B and 4C, except that, instead of a solder-based implementation or a sinter-based implementation, FIG. 4D shows an adhesive-based implementation. Specifically, as shown, a conductive adhesive material 433 is used to physically and electrically couple the first (bottom) surface of leadless discrete component 406-1 to portion 404-1 of substrate 402. For example, in this implementation, leadless discrete component 406-1 may be placed with the conductive adhesive material 433 between the bottom surface and portion 404-1. In some examples, the conductive adhesive may cure or otherwise solidify as part of the manufacturing process. In any event, conductive adhesive material 433 may ultimately function to physically and electrically couple leadless discrete component 406-1 to first portion 404-1 in a similar manner as solder material 431 and/or sintering material 432.

As described above in relation to FIGS. 3A-3D, each of the cross-sectional side views of FIGS. 4B-4D show that substrate 402 may include not only the patterned top metal surface (including portions 404-1 and 404-2) but also two additional layers representing, for example, a ceramic (or other non-conductive) tile on which the patterned metal surface is disposed, and a bottom metal surface (e.g., direct bonded copper, etc.) that may function to dissipate heat and/or provide other advantages as described above. It will be understood that these layers may be implemented in different ways or could be omitted in certain examples as may serve a particular implementation.

FIG. 5A shows illustrative aspects of compact semiconductor packaging using a leadless discrete component sandwiched between a lead and the substrate in accordance with principles described herein. Specifically, as mentioned, similar elements as have already been described are shown to make up the apparatus of FIG. 5A, including a substrate 502 having a first portion 504-1, a second portion 504-2, and a third portion 504-3 that are all electrically isolated from one another. Two leadless discrete components (both abbreviated as “LDC” in the figure) are disposed on this substrate, including a leadless discrete component 506-1 that is physically and electrically coupled to first portion 504-1 and a leadless discrete component 506-2 that is physically and electrically coupled to second portion 504-3. While not explicitly labeled in FIG. 5A, each of these leadless discrete components 506-1 and 506-2 will be understood to terminate in opposing surfaces corresponding to surfaces 108-1 and 108-2 described above. A die 510 is shown to be physically and electrically coupled to second portion 504-2 of substrate 502, and a plurality of leads 512 are shown to connect to various elements of the apparatus by way of conductive components (analogous to conductive components 114-1 through 114-3 in FIGS. 1A-1C).

In the implementations of FIGS. 5A-5D, several conductive components are shown to be implemented by wires coupled to various elements. For example, a wire 514-2 (corresponding to wire 314-2 of FIGS. 3A-3D and to clip 414-2 of FIGS. 4A-4D) is shown to electrically couple a lead 512-2 to portion 504-2 of substrate 502. Other wires not explicitly labeled in FIG. 5A will be understood to make illustrative connections that could be different for other implementations. In contrast to FIGS. 3A and 4A, however, the couplings between leads 512-1 and 512-3 are not made by wires, clips, or other such conductive components, but, rather, are made directly by virtue of the physical proximity of the leads to the elements they connect to. More particularly, as shown, leadless discrete component 506-1 may be sandwiched between substrate 502 and a lead 512-3 such that: 1) a first (bottom) surface of leadless discrete component 506-1 is physically coupled and electrically coupled to portion 504-1 of substrate 502, and 2) a second (top) surface of leadless discrete component 506-1 is physically coupled and electrically coupled to a third lead 512-3. Similarly, as further shown, portion 504-1 of substrate 502 may be directly connected (e.g., by way of soldering material, sintering material, etc.) to a first lead 512-1.

While leads 512-1 and 512-3 are shown to make direct connections (e.g., by way of soldering or sintering material or the like, rather than via a wire or clip or other such conductive component) to elements of the apparatus of FIG. 5A, other leads 512 (including lead 512-2, as mentioned above) are shown to still be connected by other means (wires in this example). As such, FIG. 5A illustrates that a combination of coupling techniques (e.g., wires, clips, direct connections, etc.) may be used in a single apparatus implementation. For example, in this case, leadless discrete component 506-1 is shown to be connected by being sandwiched between lead 512-3 and portion 504-1 of substrate 502, while leadless discrete component 506-2 is shown to be connected to portion 504-3 of substrate 502 using wires similarly as described above in relation to FIGS. 3A-3D. Similar to other examples above, a dotted line indicator labeled “FIGS. 5B-5D” is included within FIG. 5A to contextualize cross-sectional views that are depicted in each of FIGS. 5B-5D.

Accordingly, FIG. 5B shows, in a cross-sectional side view (similarly contextualized by a dotted line indicator labeled “FIG. 5A”), illustrative aspects of a solder-based implementation of the compact semiconductor packaging of FIG. 5A in accordance with principles described herein. Specifically, as shown from this side view, leadless discrete component 506-1 is sandwiched between portion 504-1 of substrate 502 and lead 512-3 and is physically and electrically coupled to these elements by solder material 531-1 (coupling portion 504-1 to the bottom surface of leadless discrete component 506-1) and solder material 531-2 (coupling the top surface of leadless discrete component 506-1 to lead 512-3). For example, in this implementation, leadless discrete component 506-1 may be soldered into place on portion 504-1 during the manufacturing process in any suitable manner. Lead 512-3 may then be soldered on the top surface of the component at a later point in the process. Alternatively, these operations could be reversed and leadless discrete component 506-1 could be first coupled to lead 512-3 and later coupled to portion 504-1 of substrate 502.

FIG. 5C shows a similar cross-sectional view as FIG. 5B, except that, instead of a solder-based implementation, FIG. 5C shows a sinter-based implementation. Specifically, as shown, a sintering material 532-1 replaces solder material 531-1 to physically and electrically couple the first (bottom) surface of leadless discrete component 506-1 to portion 504-1 of substrate 502, while a sintering material 532-2 replaces solder material 531-2 to physically and electrically couple the second (top) surface of leadless discrete component 506-1 to lead 512-3. For example, in this implementation, leadless discrete component 506-1 may be placed in between the substrate and the lead with the sintering material 532-1 and 532-2 (e.g., silver sinter, etc.) and, as part of the manufacturing process, a sintering operation (e.g., within a pressure chamber, etc.) may be performed to complete the sintering connection between the component, the substrate, and the lead.

Similarly, FIG. 5D shows a similar cross-sectional view as FIGS. 5B and 5C, except that, instead of a solder-based implementation or a sinter-based implementation, FIG. 5D shows an adhesive-based implementation. Specifically, as shown, a conductive adhesive material 533-1 is used to physically and electrically couple the first (bottom) surface of leadless discrete component 506-1 to portion 504-1 of substrate 502, while a conductive adhesive material 533-2 is used to physically and electrically couple the second (top) surface of leadless discrete component 506-1 to lead 512-3. For example, in this implementation, leadless discrete component 506-1 may be positioned with the conductive adhesive material 533-1 and 533-2 as shown during the manufacturing process. In some examples, the conductive adhesive may also cure or otherwise solidify as part of the manufacturing process. In any event, conductive adhesive material 533-1 and 533-2 may ultimately function to physically and electrically couple leadless discrete component 506-1 in a similar manner as solder material 531-1 and 531-2 and/or sintering material 532-1 and 532-2.

While each of FIGS. 5B-5D showed the same type of material (e.g., solder material, sintering material, or conductive adhesive material) being used for both couplings of leadless discrete component 506-1 as it is sandwiched between substrate 502 and lead 512-3, it will be understood that the material coupling the top surface and the bottom surface may be different in certain implementations. For example, a conductive adhesive could be used on the bottom and solder used on the top, or sintering material could be used on the bottom and solder used on the top, or any other suitable combination as may serve a particular implementation.

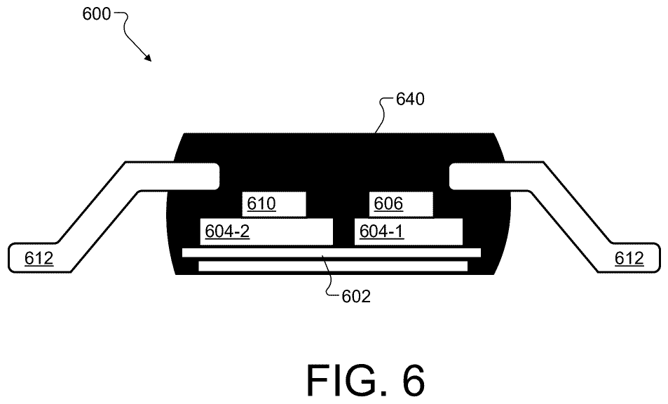

FIG. 6 shows illustrative aspects of an apparatus 600 packaged using compact semiconductor packaging in accordance with principles described herein. More particularly, while other examples have shown various elements that are being packaged together while the packaged apparatus itself is in an unfinished state, FIG. 6 shows a cross-sectional view of apparatus 600 to represent an apparatus that is finished (though not necessarily to scale and omitting various details, such as the particular conductive components used to connect elements of the apparatus within the package). As shown, the reference numbers used for apparatus 600 follow a similar pattern as other apparatuses described above. For instance, a substrate 602 (e.g., a DBC substrate or the like) is shown to include a portion 604-1 on which a leadless discrete component 606 is disposed and a portion 604-2 on which a semiconductor die 610 is disposed. Various leads 612 are also shown to be extending outwards from the package to facilitate connections to other circuitry. Moreover, apparatus 600 is shown to include a molding compound 640 that: 1) encapsulates substrate 602 (including its various portions 604-1 and 604-2), leadless discrete component 606, and semiconductor die 610; and 2) partially encapsulates each of the plurality of leads 612, while allowing part of the leads to emerge from the molding compound to facilitate other connections to be made with external circuitry.

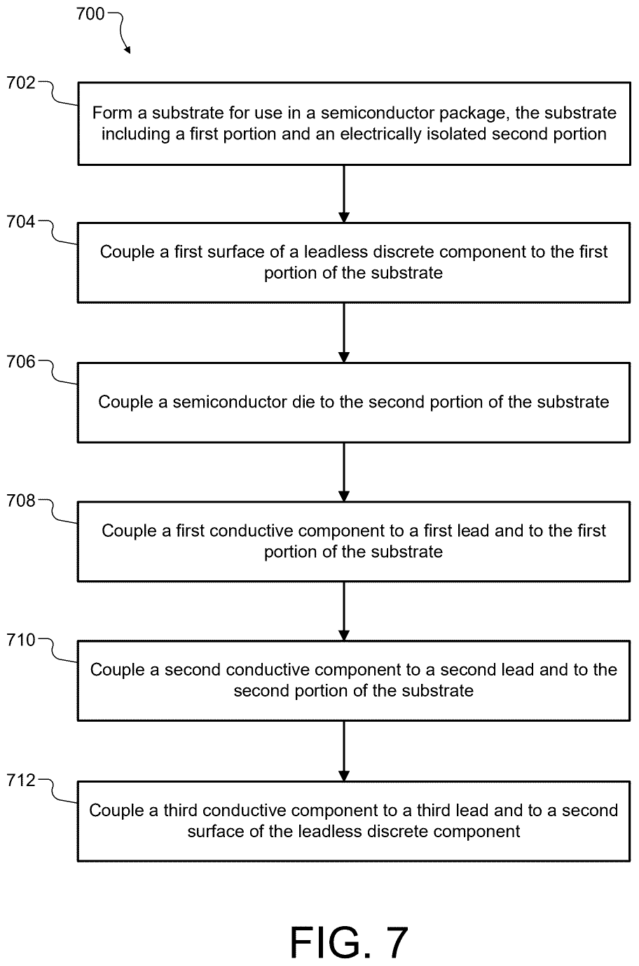

FIG. 7 shows an illustrative method 700 for constructing an apparatus with compact semiconductor packaging using a leadless discrete component in accordance with principles described herein. For example, an apparatus such as apparatus 600 or any of the other example apparatus implementations described above may be assembled or constructed based on the steps of FIG. 7. While FIG. 7 shows illustrative operations 702-712 according to one implementation, other implementations of method 700 may omit, add to, reorder, and/or modify any of the operations 702-712 shown in FIG. 7. In some examples, multiple operations shown in FIG. 7 or described in relation to FIG. 7 may be performed concurrently (e.g., in parallel) with one another, rather than being performed sequentially as illustrated and/or described. Each of operations 702-712 will now be described in more detail.

At operation 702, a substrate may be formed for use in a semiconductor package. For example, any suitable techniques for substrate preparation may be performed to create a substrate such as any of the substrates described herein. In the example of a direct bonded copper substrate, for example, operation 702 may involve preparing the ceramic substrate, preparing a copper foil (e.g., with a particular thickness to meet the application's requirements), direct bonding the copper foil to the ceramic substrate (e.g., using a high-temperature brazing process or the like), etching the desired pattern into the copper on one side of the substrate to generate a first portion and a second portion that are electrically isolated from one another, and other suitable tasks such as may be appropriate for a particular application (e.g., drilling vias, applying a solder mask, performing surface finishing, etc.).

At operation 704, a first surface of a leadless discrete component may be coupled to the first portion of the substrate. For example, the leadless discrete component may be implemented by any of the leadless discrete components described herein, such as a resistor, thermistor, capacitor, or other discrete component having a leadless package (e.g., with terminals implemented as first (bottom) and second (top) surfaces). The coupling of the first surface of the leadless discrete component at operation 704 may involve any suitable material and/or technique as may serve a particular implementation. For instance, the leadless discrete component may be coupled to the first portion using a soldering operation, a sintering operation, an operation relying on a conductive adhesive, or another suitable operation.

At operation 706, a semiconductor die is coupled to the second portion of the substrate. For example, similar to the coupling of the leadless discrete component described above in relation to operation 704, the coupling of the semiconductor die to the second portion of the substrate may involve any suitable material and/or technique as may serve a particular implementation. For instance, the semiconductor die may be coupled to the first portion using a solder material, sintering material, adhesive material, or the like.

At operation 708, a first conductive component may be coupled to a first lead of a plurality of leads and to the first portion of the substrate. For example, the first conductive component may be a wire that is coupled by a wire bonding technique, a clip that is coupled by a clip bonding technique, or the like. As another example, a direct coupling may be performed whereby the first lead is itself coupled to the first portion of the substrate using a soldering operation, sintering operation, or the like. In this case, the first conductive component would be the solder material, sintering material, or conductive adhesive material that provides the direct coupling.

At operation 710, a second conductive component may be coupled to a second lead of the plurality of leads and to the second portion of the substrate. This second conductive component may be the same or different from the first conductive component described above in relation to operation 708. For example, here again, the second conductive component may be implemented by a wire, a clip, or an amount of solder material, sintering material, conductive adhesive material, or another suitable conductor configured to electrically couple the second lead to the second portion of the substrate.

At operation 712, a third conductive component may be coupled to a third lead of the plurality of leads and to a second surface of the leadless discrete component. For example, the second surface may be opposite the first surface, such that the first surface can be considered a bottom surface while the second surface can be considered a top surface for one particular orientation of the leadless discrete component. As with the first and second conductive components above, the third conductive component may be any of the conductive components described herein and may be the same or different from the first and second conductive components described above.

Various ways that each of operations 702-712 may be performed have been described. To be more specific, a few possible implementations are now described that correspond with particular implementations illustrated and described above. As a first possible implementation, the first surface of the leadless discrete component may be coupled to the first portion of the substrate at operation 704 apart from the third lead. The third conductive component coupled at operation 712 may then be a wire that is coupled to the third lead and the second surface of the leadless discrete component using a wire bonding technique. This type of implementation is illustrated specifically in FIGS. 3A-3D.

As another possible implementation, the first surface of the leadless discrete component could again be coupled to the first portion of the substrate at operation 704 apart from the third lead. The third conductive component coupled at operation 712 may then be a clip extending between the third lead and the second surface of the leadless discrete component. This type of implementation is illustrated specifically in FIGS. 4A-4D.

As yet another possible implementation, the leadless discrete component may be sandwiched between the first portion of the substrate and the third lead. As such, and as mentioned above, the third conductive component in this type of implementation could be one of a solder material, a sintering material, or a conductive adhesive material. This type of implementation is illustrated specifically in FIGS. 5A-5D.

As stated above, concepts related to compact semiconductor packaging using leadless discrete components have been described with reference to FIGS. 2, 3A-3D, 4A-4D, 5A-5D, 6, and 7. Related concepts in which leadless temperature sensors (a particular type of leadless discrete component) may be used to enable on-die temperature sensing within electronic components will now be described with reference to FIGS. 8, 9A-9B, 10-12, and 13A-13B.

In a similar way as FIG. 2 illustrated a contrast between conventional semiconductor packaging and compact semiconductor packaging using leadless discrete components, FIG. 8 contrasts illustrative aspects of conventional temperature sensor placement within a device package with on-die leadless temperature sensor placement within a device package in accordance with principles described herein. More particularly, an apparatus 800-A that uses a surface mount temperature sensor placed near (but not near enough to make physical contact with) the semiconductor die is illustrated on the left, while an apparatus 800-B that uses a leadless temperature sensor disposed directly on (and therefore making direct physical contact with) the semiconductor die is illustrated on the right. Each of these apparatuses will now be described, including the ways in which they contrast so that certain advantages are provided by apparatus 800-B as compared to apparatus 800-A.

Apparatus 800-A includes a substrate 802 similar to other substrates described herein. In this example, the substrate 802 is shown to include three electrically isolated portions: a portion 804-1 on which a semiconductor die 810 is disposed, and portions 804-2 and 804-3 on which a surface mount temperature sensor 806-A is placed. As with other examples described above, the nature of the surface mount packaging may require isolated pads for each lead of the surface mount temperature sensor 806-A, as well as certain clearances, traces (not shown), and so forth. Electrical connections are not explicitly shown in FIG. 8, but it will be understood that surface mount temperature sensor 806-A, semiconductor die 810, portions 804-1 to 804-3 of substrate 802, and other elements (not explicitly shown) may be electrically connected to a plurality of leads 812 in any manner as may serve a particular implementation.

Similar to apparatus 800-A, apparatus 800-B also includes a substrate 802 with a portion 804 on which a semiconductor die 810 is disposed. In contrast to apparatus 800-A, however, apparatus 800-B is shown to only include a single portion 804. This is because, in place of the surface mount temperature sensor 806-A of apparatus 800-A, apparatus 800-B uses the leadless temperature sensor 806-B that is shown to be disposed directly on the top surface of the semiconductor die 810. Here again, a plurality of leads 812 will be understood to be electrically connected to these various elements, though electrical connections are not explicitly shown in FIG. 8.

For both apparatuses 800-A and 800-B, the semiconductor die 810 will be assumed to act as a primary source of heat when these electronic components are operating. For example, as has been described, the semiconductor die could implement a power transistor (e.g., a power MOSFET) through which considerable current is flowing to thereby create considerable heat. A heat map 850 is shown for both apparatuses 800-A and 800-B to illustrate where heat may originate and how the heat may dissipate with distance from the semiconductor die heat source. Specifically, as illustrated by concentric circles centered at each semiconductor die 810, a significant amount of heat may be concentrated at the die. As the circles of heat maps 850 grow larger and get farther apart moving away from the respective semiconductor dies 810, this will be understood to represent a dissipation of heat energy as it is absorbed by a larger and larger area around the heat source. The spread of the heat represented by heat maps 850 will also be understood to take finite time, and not occur instantaneously. As such, the larger outside circles of heat maps 850 may represent heat that has transferred at a later time than heat closer to the center.

FIG. 8 shows that the placement of surface mount temperature sensor 806-A may be near enough to the semiconductor die 810 in apparatus 800-A to measure much of the heat energy given off by semiconductor die 810, but the heat maps indicate that the temperature at this location on the substrate 802 is not necessarily the same temperature as right on semiconductor die 810, since some of the heat has dissipated before reaching that corner of the substrate. The result is that the conventional surface mount temperature sensor 806-A may approximate the temperature of semiconductor die 810 but may not reflect that temperature with as much accuracy as it could if the temperature sensor were closer to the center of the heat map. Similarly, the placement of surface mount temperature sensor 806-A is such that it may not take much time for the measured temperature to reflect the heat at the source, but there will be at least some delay as heat convection gradually spreads from the die and across the substrate and through the package.

In contrast, the placement of leadless temperature sensor 806-B right on the surface of the semiconductor die 810 in apparatus 800-B places this temperature sensor at the center of heat map 850. Accordingly, as compared to measurements by surface mount temperature sensor 806-A, measurements made using leadless temperature sensor 806-B will more accurately reflect that actual temperature of the semiconductor die 810 (given that the temperature sensor is in contact with the die such that there is no measurement gap or thermal loss) and will do so in a more timely manner (since there will also be no delay for heat convection given the sensor's direct contact with the die).

While not necessarily the focus, as was the case for the compact semiconductor packaging examples described above, the contrast between apparatuses 800-A and 800-B in FIG. 8 shows that, without needing area for multiple portions 804-1, 804-2, and 804-3 (as are needed in apparatus 800-A), apparatus 800-B may also benefit from a more compact substrate 802 and narrower leads 812. Various advantages attending this compactification of the apparatus footprint have been described.

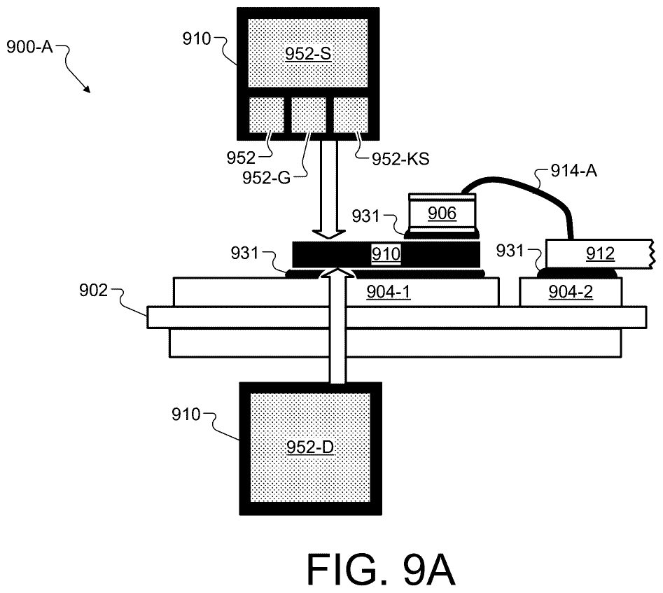

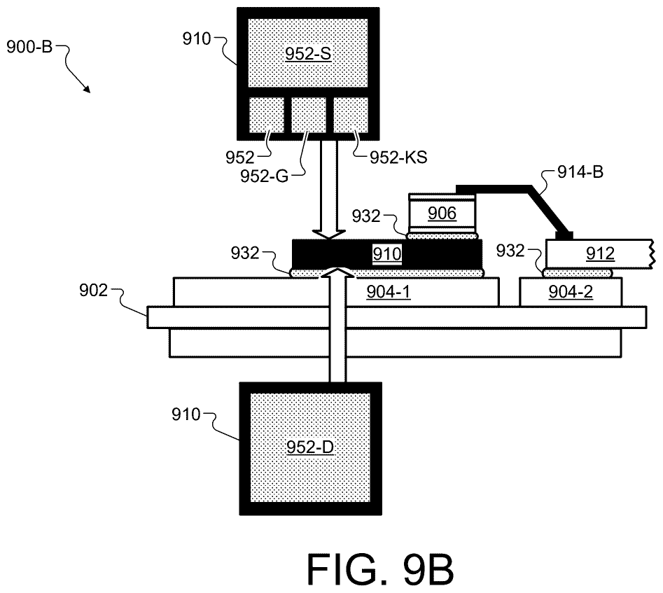

FIGS. 9A and 9B each show, in respective cross-sectional views, illustrative aspects of example implementations of on-die temperature sensing within an electronic component in accordance with principles described herein. Specifically, FIG. 9A shows an apparatus 900-A implementing one example implementation of an electronic component employing on-die temperature sensing, while FIG. 9B shows an apparatus 900-B implementing another example implementation of an electronic component employing similar on-die temperature sensing.

Each of apparatuses 900-A and 900-B is shown to include a substrate 902 with multiple portions 904-1 and 904-2. A leadless temperature sensor 906 (which, though not labeled in FIGS. 9A-9B, is shown to have top and bottom surfaces such as described above in relation to surfaces 108-1 and 108-2) is also included in both apparatuses and shown to be disposed on top of respective semiconductor dies 910 that are themselves disposed on portion 904-1 of substrate 902. While most of the electrical connections are not explicitly shown in these figures, a lead 912 is shown to be coupled to portion 904-2 of substrate 902 and to be electrically connected by a conductive component to the leadless temperature sensor 906. Pad layout diagrams of semiconductor die 910 are also included in FIGS. 9A and 9B to show several example pads 952. Specifically, a pad layout diagram above semiconductor die 910 in the figure represents a first (top) surface of semiconductor die 910 that faces away from substrate 902 (and that includes at least pads 952-S, 952-G, and 952-KS), while a pad layout diagram below semiconductor die 910 in the figure represents a second (bottom) surface of semiconductor die 910 that faces substrate 902 (and that includes at least a pad 952-D).

While apparatuses 900-A and 900-B are similar in the above respects, the implementations are shown to differ with regard to the way elements may be coupled together (similar to various implementations of compact semiconductor packaging using leadless discrete components described and illustrated above). For example, while the leadless temperature sensor 906 and the lead 912 are shown to be electrically coupled by a wire 914-A in apparatus 900-A, these elements are instead shown to be electrically coupled by a clip 914-B in apparatuses 900-B. Additionally, while the surfaces of the leadless temperature sensor 906, semiconductor die 910, and lead 912 are shown to be coupled using solder material 931 in apparatus 900-A, these same elements are shown to be coupled using sintering material 932 in apparatuses 900-B. It will be understood that these example connections are shown for purposes of illustration and, as laid out more thoroughly above, may be applied in various other combinations (e.g., clips and solder material, wires and sintering material, etc.) including combinations that use other coupling mechanisms (e.g., wires or clips and conductive adhesive material, etc.).

The elements illustrated in FIGS. 9A and 9B may be implemented in similar ways as corresponding elements that have been described above. Each of these elements will also now be described in more detail.

Substrate 902 may be implemented in any of the ways described herein, including as a direct-bonded metal (DBM) substrate that includes a ceramic plate (the middle layer) to which a patterned layer of conductive material (portions 904-1 and 904-2) is bonded on at least one side of the ceramic plate (and, in this example, on both sides, though the conductive material on the bottom of the ceramic plate may not be patterned in the same way as the top or patterned at all).

In some implementations, a direct-bonded metal (DBM) substrate may be used that includes an insulating layer (e.g., the ceramic plate) disposed between a first metal layer (e.g., portions 904-1 and 904-2) and a second metal layer (on the bottom of the substrate, not explicitly labeled). The insulating layer can be, for example, a ceramic layer. In some implementations, the insulating layer can be or can include, for example, a ceramic material such as alumina (Al₂O₃) or aluminum nitride (AlN)).

In some implementations, the direct-bonded metal (DBM) substrate can be formed by bonding one or more of the metal layers (e.g., the first metal layer, the second metal layer, etc.) to the insulating layer (e.g., a ceramic layer or the like). For example, the one or more metal layers may be bonded to the insulating layer using, for example, a high-temperature process.

In some implementations, the first metal layer and/or the second metal layer can be configured to function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer can be or can include a patterned metal layer including one or more electrically conductive traces. In some implementations, the first metal layer and/or the second metal layer can be or can include a patterned layer configured to form one or more electrical circuits, one or more conductive blind and/or through vias, and so forth.

In some implementations, the DBM substrate can be, or can include, a direct bonded copper (DBC) substrate. In some implementations, such as in DBC substrate implementations, the first metal layer and/or the second metal layer may be implemented as copper layers.

Leadless temperature sensor 906 may be implemented by any suitable temperature sensor component that is packaged in the ways that have been described and illustrated (i.e., with top and bottom surfaces acting as terminals so as to be bondable on top of the semiconductor die, rather than having leads such as those of a surface-mount device). For example, leadless temperature sensor 906 may be a leadless thermistor such as a negative temperature coefficient (NTC) thermistor in certain implementations. An NTC thermistor (such as is shown to implement leadless temperature sensor 906 in apparatus 900-A and apparatuses 900-B) can be attached to a die (e.g., semiconductor die 910) using adhesive or other connections (e.g., solder material 931, sintering material 932, etc.) and can be operated through an electrical circuit configuration. An advantage of this on-die placement, as has been described, is that, unlike the typical placement for an NTC thermistor attached to a conductive substrate, this NTC thermistor placement allows for direct measurement of heat generated by the die without thermal loss or added delay. Leadless temperature sensor 906 may have other characteristics in common with other leadless discrete components described herein. For example, materials used for the top-side and bottom-side terminations of the component may be similar to those that have been described.

Semiconductor die 910 may be implemented by any of the types of semiconductor dies described herein or other dies as may be packaged in this type of device packaging in other implementations. As one example, semiconductor die 910 may be implemented as a transistor (e.g., a MOSFET, an insulated-gate bipolar transistor (IGBT), or the like). For instance, the transistor could be a power MOSFET fabricated using a silicon carbide (SiC) semiconductor, a power MOSFET fabricated using a silicon (Si) semiconductor or another suitable semiconductor, or the like. Power MOSFETS may be used in power electronics applications such as power supplies, motor drives, power inverters, and so forth. As compared to other transistors (e.g., standard MOSFETS that are not power MOSFETS), power MOSFETS may be configured to handle significantly higher power levels, may use different fabrication techniques and packaging to improve thermal dissipation and reduce internal resistance, and may require higher gate drive voltages and currents to ensure proper operation. In certain implementations, the semiconductor die 910 may represent, rather than a single transistor such as a power MOSFET, an integrated circuit (IC) having multiple transistors (and possibly other elements) integrated onto the die.

The pad layouts for semiconductor die 910 shown in FIGS. 9A and 9B provide an example in which the transistor implemented by semiconductor die 910 is a power MOSFET including a source pad 952-S, a gate pad 952-G, and a sensor pad 952-KS (e.g., a Kelvin sense pad of the transistor) on the first (top) surface of semiconductor die 910 facing away from substrate 902, as well as a drain pad 952-D on the second (bottom) surface of semiconductor die 910 facing substrate 902. The first surface further shows an additional pad 952 that may be another sense pad (e.g., another Kelvin sense pad similar to sensor pad 952-KS) or another pad of the transistor as may serve a particular implementation.

In this example, it will be understood that source pad 952-S may implement the pad of semiconductor die 910 on which leadless temperature sensor 906 is disposed, gate pad 952-G (also on the surface of the semiconductor die facing away from substrate 902) may be electrically isolated from source pad 952-S, sensor pad 952-KS (also on the surface of the semiconductor die facing away from substrate 902) may be electrically connected to source pad 952-S, and drain pad 952-D may be disposed on an opposite surface of semiconductor die 910 (i.e., the surface facing substrate 902). As will be illustrated and described in more detail below, wire 914-A may be electrically coupled to the first (top) surface of the leadless temperature sensor 906 and one lead 912 (e.g., a temperature sense output lead), while another electrical connection (not shown in FIGS. 9A-9B) may be electrically coupled to sensor pad 952-KS of semiconductor die 910 and a different lead 912 (e.g., a temperature sense input lead).

Because of the electrical connection between sensor pad 952-KS and source pad 952-S, this latter connection may amount to an (indirect) coupling between the second (bottom) surface of the leadless temperature sensor 906 and the lead 912. In other words, the Kelvin sense pad of sensor pad 952-KS (and, therefore, the lead 912 that is connected to this pad) may be overloaded with two functions. First, this lead 912 may be configured to serve as a Kelvin sense input and/or output. This Kelvin sense input/output may be used to measure the voltage drop across the device more accurately, since, in high-power applications, even small resistances in connections can lead to significant voltage drops and affect the accuracy of current and power measurements. A Kelvin connection therefore uses a separate pair of wires to sense the voltage, minimizing the impact of these resistance drops. Second, this lead 912 may also (simultaneously) be configured to serve as a temperature sense input and/or output (e.g., depending on whether leadless temperature sensor 906 is bidirectional, how it is oriented, etc.) for measurements by the leadless temperature sensor 906.

As described above, apparatus 900-A and apparatuses 900-B provide example combinations of ways that electrical and physical couplings can be made within apparatuses implementing on-die temperature sensing. Between these examples and others that have been mentioned, it will be understood that the surface of leadless temperature sensor 906 may be coupled to the pad of the semiconductor die (e.g., source pad 952-S) via a solder material, a sintering material, an adhesive, or another suitable way. Additionally, it will be understood that at least one of wires or clips may be used to electrically couple a plurality of leads 912 with other elements of the apparatus.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder or solder material.

In some implementations, sintering can be or can include a process of fusing particles together into one solid mass by using, for example, a combination of pressure and/or heat that is applied without melting the materials. In some implementations, sintering can include making a material (e.g., a powdered sintering material) coalesce into a solid or porous mass by heating the material (as well as, in some cases, compressing the material) without liquefaction. In some implementations, materials that can be used for sintering include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder material, a sintering material (e.g., silver, copper), and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

One or more wirebonds, which can be included in at least some of the implementations described herein, can be replaced with a conductive component. For example, in some implementations, one or more wirebonds can be replaced with a conductive clip. The conductive clip can be coupled to another component (e.g., an attach pad, a leadframe, a semiconductor die, etc.) using, for example, a solder (e.g., a soldering process), a sintered coupling (e.g., a sintering process), a weld, or the like. In some implementations, one or more wirebonds and/or clips can function as an input and/or output power terminal, a signal terminal, a power terminal, or another suitable terminal.

Implementations of on-die temperature sensing within an electronic component described above have included apparatuses with singular semiconductor dies (the singular semiconductor die 910 in each of apparatuses 900-A and 900-B, for example). In other implementations, however, it will be understood that a plurality of semiconductor dies may be employed. For example, along with a first semiconductor die implementing a first transistor and having a first pad on its surface, an apparatus could further include a second semiconductor die disposed on the substrate, the second semiconductor die implementing a second transistor and including a second pad on a surface of the second semiconductor die facing away from the substrate. Just as one or more leads may be coupled with the surface of the first semiconductor die, the plurality of leads of this apparatus could further include one or more leads electrically coupled with the surface of the second semiconductor die (e.g., with various pads on the surface, etc.).

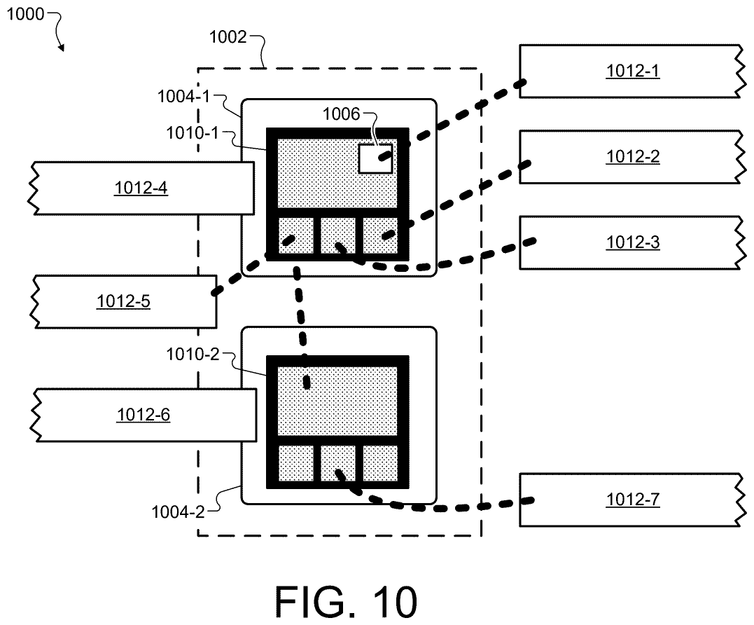

To illustrate, FIG. 10 shows certain aspects of an implementation of a multi-die electronic component featuring on-die temperature sensing in accordance with principles described herein. More particularly, as shown in FIG. 10, an apparatus 1000 includes a substrate 1002 that includes at least two portions 1004-1 and 1004-2 that are electrically isolated from one another. Within portion 1004-1 of substrate 1002, a first semiconductor die 1010-1 is shown to be disposed and to host, on its source pad (not explicitly labeled in FIG. 10 but the same as source pad 952-S of semiconductor die 910 described above), a leadless temperature sensor 1006. Within portion 1004-2 of substrate 1002, a second semiconductor die 1010-2 is also shown to be disposed with its own pads (also the same as the pads of semiconductor die 910 described above).

In some implementations, first semiconductor die 1010-1 and second semiconductor die 1010-2 may each implement identical transistors or at least similar transistors fabricated using the same type of semiconductor (e.g., silicon, silicon carbide, etc.). In other implementations, however, the first semiconductor die 1010-1 and the second semiconductor die 1010-2 may be hybrid dies fabricated using different semiconductors. For example, first semiconductor die 1010-1 may be a silicon (Si) die and second semiconductor die 1010-2 may be a silicon carbide (SiC) die in some of these implementations.

In some implementations, one or more semiconductor dies (e.g., one or more semiconductor components) can be, or can include, a power semiconductor die. In some implementations, a semiconductor die may implement one or more transistors or a portion of a transistor or transistor-based circuit. For example, one or more of a MOSFET device, an IGBT, an IC, an inverter, a power conversion circuit, a bridge circuit, a fast recovery diode (FRDs), a diode, or the like could be implemented on a semiconductor die. In some implementations, a component implemented (or partially implemented) by one or more semiconductor dies can be used or included within an electrical vehicle (EV).

More than one semiconductor die can be included in the implementations described herein. In some implementations involving more than one semiconductor die, the different semiconductor dies can be fabricated using different semiconductor substrates (e.g., a silicon carbide (SiC) substrate, a silicon (Si) substrate, a gallium nitride (GaN) substrate, etc.). In other words, different semiconductor dies may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second semiconductor die, for example, by an electrical connection (e.g., a wirebond, an electrical clip, a joint, etc.) extending directly from the first die to the second die, or connected through a trace formed in the first conductive layer (e.g., a metal layer) of an electronic power substrate. The first of the plurality of semiconductor dies may be also connected to leadframe posts by electrical connections such as wirebonds or clips.

In example implementations, a package (e.g., a power module) can be a hybrid device package that includes a semiconductor die or a plurality of semiconductor dies that are integrated onto to a unifying electronic power substrate (e.g., a ceramic substrate, a DBM or DBC substrate, an AMB substrate, an elastomeric substrate, an organic substrate, a phenolic substrate, or a PCB/FR-4 substrate). In some implementations, multiple semiconductor devices can be fabricated on the same substrate (such as a SiC substrate suitable for high power applications).

In some implementations, one or more semiconductor dies can be embedded within a layer (rather than surface mounted). For example, one or more semiconductor dies can be disposed within a recess or cavity of a layer (e.g., a substrate, a printed circuit board, a conductive layer, an insulating layer, etc.).

Dotted lines shown in FIG. 10 will be understood to represent any of the various conductive components described herein (e.g., wires, clips, joints, etc.) to form electrical connections between the elements shown. These electrical connections are shown to connect elements to one another and/or to various leads 1012-1 through 1012-6. For instance, in the example of apparatus 1000, leads 1012-1 and 1012-2 are shown to serve, respectively, as temperature sense output and input leads for reading information from leadless temperature sensor 1006. While lead 1012-1 is directly connected to the top surface of leadless temperature sensor 1006 (i.e., the surface facing away from first semiconductor die 1010-1), which in this example may be the output of an NTC thermistor implementing leadless temperature sensor 1006, lead 1012-2 is shown to be connected to the Kelvin sense pad of first semiconductor die 1010-1. As described above, since the Kelvin sense pad is internally connected to the source pad where leadless temperature sensor 1006 is disposed, and since the bottom surface of leadless temperature sensor 1006 is in direct contact with this source pad, lead 1012-2 is thereby indirectly electrically coupled with the bottom surface of leadless temperature sensor 1006. As further described above, it will also be understood that lead 1012-2 may function as a Kelvin sense lead (performing both roles simultaneously).

In this example, a lead 1012-3 is shown to be connected to the gate pad of 1010-1, thereby allowing a signal on lead 1012-3 to control current flow through the transistor of first semiconductor die 1010-1. The drain pad of the transistor of first semiconductor die 1010-1 (connected on the bottom side to portion 1004-1 of substrate 1002, as illustrated above) is then shown to be electrically connected to the source pad of second semiconductor die 1010-2. Lead 1012-4 also connects to the drain of first semiconductor die 1010-1 (by way of direct connection to portion 1004-1), while lead 1012-5 connects to the other sense pad, lead 1012-6 connects to the drain of second semiconductor die 1010-2 (by way of direct connection to portion 1004-2), and lead 1012-7 connects to the gate of second semiconductor die 1010-2. In this way, an inverter circuit may be formed in which alternating current is provided on lead 1012-4, and direct current is provided between leads 1012-5 and 1012-6 (with leads 1012-1 to 1012-3 and 1012-7 being used for control and sensor measurement, as has been described).

While the singular leadless temperature sensor 1006 shown in FIG. 10 may serve to monitor the temperature of first semiconductor die 1010-1 very accurately and timely and to suitably monitor the temperature of second semiconductor die 1010-2 as well (albeit with at least some reduction in accuracy and timeliness), it may be desirable in certain implementations for both semiconductor dies 1010-1 and 1010-2 to be monitored with dedicated on-die leadless temperature sensors. More particularly, along with a first leadless temperature sensor such as leadless temperature sensor 1006, an apparatus may further include a second leadless temperature sensor disposed on a second pad (e.g., the sensor pad) of second semiconductor die 1010-2. The plurality of leads may then further include an additional lead electrically coupled with a surface of the second leadless temperature sensor facing away from the surface of the second semiconductor die.

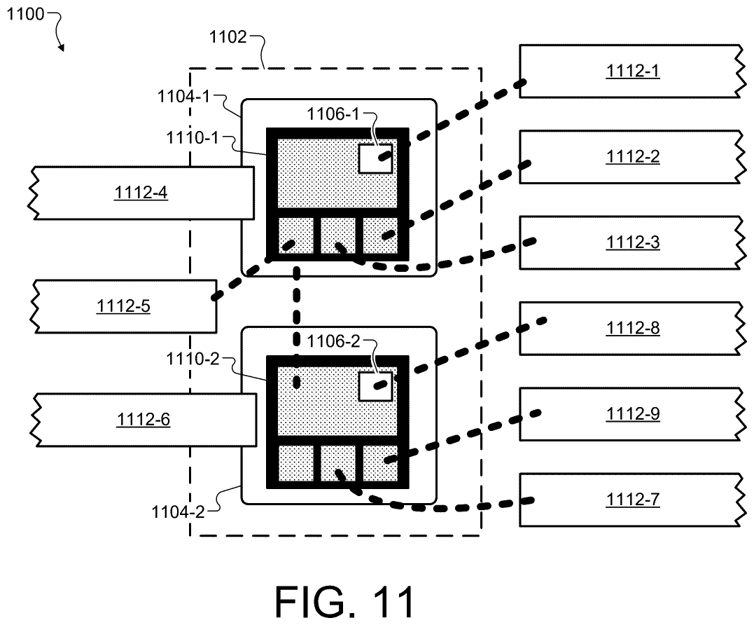

To illustrate, FIG. 11 shows illustrative aspects of an implementation of a multi-die electronic component featuring dual on-die temperature sensing in accordance with principles described herein. As shown, similar to FIG. 10, FIG. 11 includes an apparatus 1100 with a substrate 1102 featuring two portions 1104-1 and 1104-2 that are electrically isolated from one another. On portion 1104-1, a first leadless temperature sensor 1106-1 is shown to be disposed on the source pad of a first semiconductor die 1110-1 implementing a first power MOSFET. Similarly, on portion 1104-2, a second leadless temperature sensor 1106-2 is shown to be disposed on the source pad of a second semiconductor die 1110-2 implementing a second power MOSFET.

Leads 1112-1, 1112-2, 1112-3, 1112-4, 1112-5, 1112-6, and 1112-7 are shown to have corresponding connections with similarly-numbered leads 1012-1 to 1012-7, described above. Moreover, two additional leads 1112-8 and 1112-9 are shown to be included in apparatus 1100 to connect to the second leadless temperature sensor 1106-2. Specifically, in the same way as described above for the first leadless temperature sensor, a direct electrical connection is shown between lead 1112-8 and a surface of the second leadless temperature sensor 1106-2 that is facing away from semiconductor die 1110-2. An indirect electrical connection (by way of an internal connection between the Kelvin sense pad and the source pad of semiconductor die 1110-2) is then shown between lead 1112-9 (connected to the Kelvin sense pad) and the other (bottom) surface of the second leadless temperature sensor 1106-2 that is in physical contact with the source pad of the semiconductor die 1110-2 (which is itself internally connected to the Kelvin sense pad).

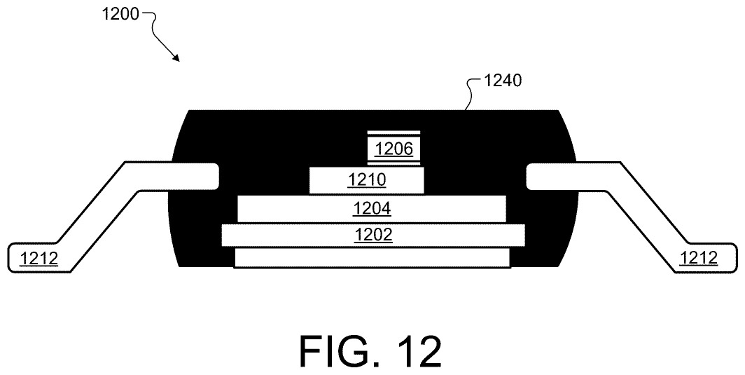

FIG. 12 shows illustrative aspects of a packaged apparatus 1200 configured to perform on-die temperature sensing in accordance with principles described herein. More particularly, while other examples have shown various elements that are being packaged together while the packaged apparatus itself is in an unfinished state, FIG. 12 shows a cross-sectional view of apparatus 1200 to represent an apparatus that is finished. While representing a finished product, however, it will be understood that apparatus 1200 is not necessarily to scale and omits various details, such as the particular conductive components (i.e., electrical connections) that may be used to connect elements of the apparatus within the package. In apparatus 1200, a substrate 1202 (e.g., a DBM substrate or the like) is shown to include a portion 1204 on which a semiconductor die 1210 is disposed. A leadless temperature sensor 1206 is then disposed on semiconductor die 1210. A plurality of leads 1212 is also shown to be extending outwards from the package to facilitate connections to other circuitry (e.g., to all apparatus 1200 to be soldered or otherwise connected to a printed circuit board (PCB) or the like).

Along with the various elements that have been described in more detail above, apparatus 1200 is also shown to include a molding compound 1240 that at least partially encapsulates substrate 1202 (including portion 1204), semiconductor die 1210, leadless temperature sensor 1206, and the plurality of leads 1212. More particularly, semiconductor die 1210, leadless temperature sensor 1206, and portion 1204 of substrate 1202 are shown to be entirely encapsulated within molding compound 1240, while a bottom portion of substrate 1202 and the plurality of leads 1212 are shown to be partially encapsulated, thereby allowing for direct heat transfer away from substrate 1202 and allowing parts of the leads to emerge from the molding compound 1240 to facilitate other connections to be made with external circuitry. Apparatus 1200 may be used in any suitable application of external circuitry. In one example, for instance, apparatus 1200 may be an integrated circuit implementing a power module configured for use in an automotive application.

In some implementations, a molding or encapsulation material such as molding compound 1240 can be or can include a non-conducting layer/material. In various examples the molding material may be or include an organic material (e.g., a polymer or plastic material such as epoxy, silicone, phenolic resin, etc.), an inorganic material (e.g., a non-conductive ceramic or conductive metal material, etc.), and/or other suitable materials as may serve a particular implementation.

In some implementations, a module (e.g., an apparatus including a semiconductor device within a package) can be included in another module. The module can be referred to as a package. For example, one or more modules can be one or more sub-modules included within another module. In other words, a first module can be included as a sub-module within a second module. Referring more particularly to modules such as are implemented by apparatus 1200, these may serve as sub-modules to a larger module such as a circuit, system, or device (e.g., an automotive system or device) that employs apparatus 1200 and may include a plurality of instances of apparatus 1200.

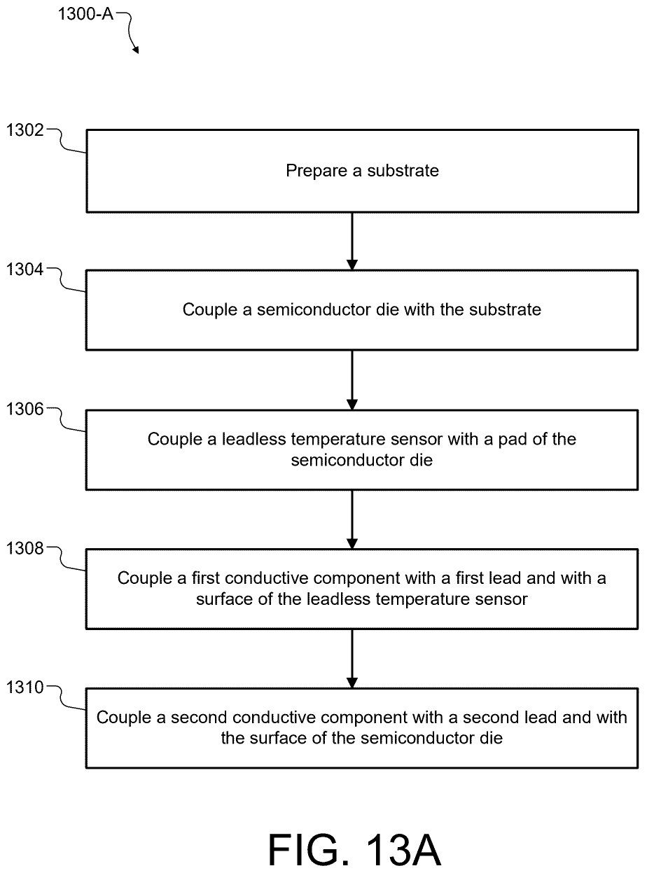

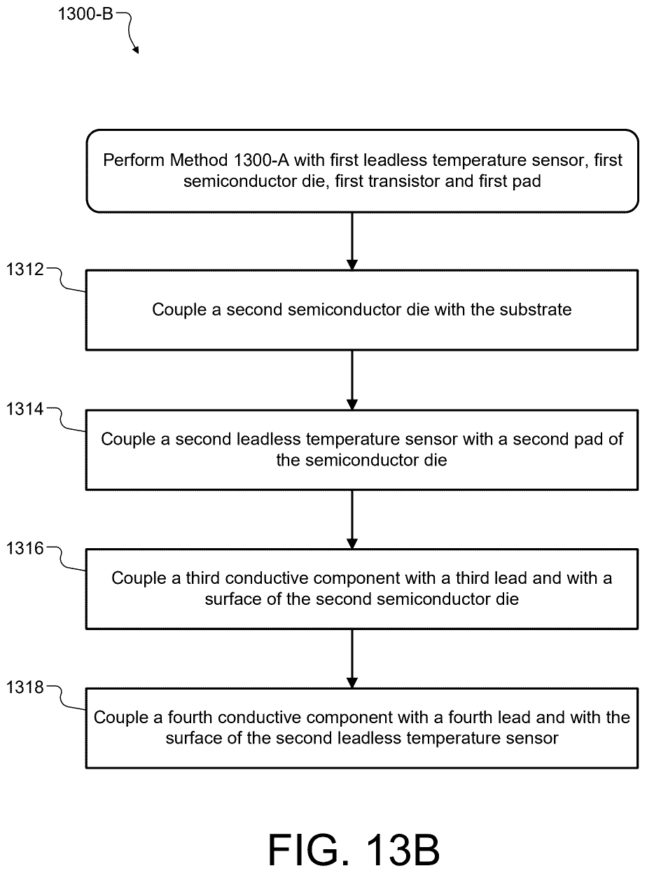

FIG. 13A shows an illustrative method 1300-A for constructing an apparatus employing on-die temperature sensing using a leadless temperature sensor in accordance with principles described herein. While method 1300-A focuses on a singular semiconductor die (e.g., such as illustrated above, for example, in FIGS. 1C, 9A, and 9B), FIG. 13B shows an additional method 1300-B for constructing a multi-die apparatus employing on-dic temperature sensing using multiple leadless temperature sensors (e.g., such as illustrated above, for example in FIG. 11). As such, for example, apparatuses such as apparatuses 100-C, 800-B, 900-A, 900-B, or the like, may be assembled or constructed based on the steps of method 1300-A, while apparatuses such as apparatus 1100 may be assembled or constructed based on the steps of method 1300-B. An apparatus such as apparatus 1000 may be assembled using small variants of method 1300-B (omitting the second leadless temperature sensor and connections thereto).

While FIGS. 13A-13B shows illustrative operations according to certain implementations, it will be understood that other implementations of these construction methods may omit, add to, reorder, and/or modify any of the operations shown in FIGS. 13A-13B. In some examples, multiple operations shown in FIGS. 13A-13B or described in relation to FIGS. 13A-13B may be performed concurrently (e.g., in parallel) with one another, rather than being performed sequentially as illustrated and/or described. Each of the operations of methods 1300-A and 1300-B will now be described in more detail.

At operation 1302, a substrate may be prepared. For example, the substrate prepared at operation 1302 may be a DBM substrate including a ceramic plate to which a patterned layer of conductive material is bonded on at least one side of the ceramic plate, as has been described. This DBM substrate may be prepared to have the proper patterning (e.g., shapes of various electrically-isolated portions, etc.) by being fabricated or otherwise procured (e.g., from a supplying manufacturer) with the desired characteristics.

At operation 1304, a semiconductor die may be coupled (e.g., physically attached using solder or sintering material, etc.) with the substrate prepared at operation 1302. For example, the semiconductor die may implement a transistor (e.g., a power MOSFET fabricated using a SiC semiconductor) and include one or more pads on a surface of the semiconductor die facing away from the substrate. In examples where the semiconductor die is a power MOSFET, the pads may include, for instance: 1) a source pad, 2) a gate pad on the surface of the semiconductor die facing away from the substrate and electrically isolated from the source pad, 3) a sensor pad on the surface of the semiconductor die facing away from the substrate and electrically connected to the source pad, and 4) a drain pad on a surface of the semiconductor die facing the substrate.

At operation 1306, a leadless temperature sensor may be coupled (e.g., physically attached using a conductive adhesive bonding or other suitable material) with a pad of the semiconductor die. For example, the leadless temperature sensor may be implemented as an NTC thermistor or other suitable leadless temperature sensor. In examples such as described above, where the transistor implemented by the semiconductor die is a power MOSFET, the source pad may implement the pad of the semiconductor die on which the leadless temperature sensor is disposed.

At operation 1308, a first conductive component (e.g., a wire, a clip, or another suitable electrical connection) may be coupled with a first lead of a plurality of leads and with a surface of the leadless temperature sensor facing away from the surface of the semiconductor die. In other words, the first conductive component may make the electrical connection between the first lead and the top surface (e.g., the output termination) of the leadless temperature sensor.

At operation 1310, a second conductive component (e.g., similar to the first conductive component) may be coupled with a second lead of the plurality of leads and with the surface of the semiconductor die. For example, this coupling of the second conductive component with the surface of the semiconductor die may be performed by coupling the second conductive component with the lead and the sensor pad of a power MOSFET (assuming, as has been described, that the sensor pad is internally connected to the source pad and that the bottom surface (e.g., the input termination) of the leadless temperature sensor is physically coupled to the source pad.

While not explicitly shown in FIG. 13A, method 1300-A may include other operations such as at least partially encapsulating, within a molding compound, the substrate, the semiconductor die, the leadless temperature sensor, and the plurality of leads, as well as for making other electrical connections and finishing the device package in various ways.

Turning to method 1300-B of FIG. 13B, this method for constructing a multi-die apparatus employing dual on-die temperature sensing (i.e., on-die temperature sensing for multiple leadless temperature sensors within a same device package) is shown to include a performance of method 1300-A (to integrate the first leadless temperature sensor and the first semiconductor die implementing the first transistor with the first pad). The additional operations of method 1300-B will be understood to be intermingled with corresponding operations as they are performed in furtherance of method 1300-A.

At operation 1312, a second semiconductor die is coupled (e.g., physically attached) with the substrate (e.g., the same DBM substrate prepared at operation 1302 described above). This second semiconductor die may implement a second transistor and may include a second pad on a surface of the second semiconductor die facing away from the substrate.

At operation 1314, a second leadless temperature sensor may be coupled with the second pad of the second semiconductor die. For example, this pad could be the source pad, as has been described and illustrated.

At operation 1316, a third conductive component may be coupled with a third lead of the plurality of leads and with the surface of the second semiconductor die. More particularly, this coupling may be between the third conductive component and either the source pad on which the second semiconductor die is coupled or a sensor pad (e.g., a Kelvin sense pad) that is internally electrically connected with the source pad, as has been described.

At operation 1318, a fourth conductive component may be coupled with a fourth lead of the plurality of leads and with a surface of the second leadless temperature sensor facing away from the surface of the second semiconductor die.

The following examples describe implementations (e.g., apparatuses, methods, devices, etc.) of temperature sensing within an electronic component, and, in many examples, on-die temperature sensing within the electronic component.

Example 1: An apparatus comprising: a substrate; a semiconductor die disposed on the substrate, the semiconductor die implementing a transistor; a leadless temperature sensor having a first surface and a second surface opposite the first surface, the leadless temperature sensor being configured to measure a temperature of the semiconductor die; and a plurality of leads including a first lead and a second lead, the first lead electrically coupled with the first surface of the leadless temperature sensor and the second lead electrically coupled with the second surface of the leadless temperature sensor.

Example 2: The apparatus of any of the preceding examples, wherein: the leadless temperature sensor is disposed on a pad of a surface of the semiconductor die facing away from the substrate, the second surface of the leadless temperature sensor being physically coupled to the pad; and the second lead is electrically coupled with the second surface of the leadless temperature sensor by being coupled to the surface of the semiconductor die.

Example 3: The apparatus of any of the preceding examples, wherein: the substrate includes a first portion and a second portion, the first portion being electrically isolated from the second portion; the leadless temperature sensor is disposed on the first portion and the semiconductor die is disposed on the second portion; and the second lead is electrically coupled with the second surface of the leadless temperature sensor by being coupled to the second portion of the substrate.

Example 4: An apparatus comprising: a substrate; a semiconductor die disposed on the substrate, the semiconductor die implementing a transistor and including a pad on a surface of the semiconductor die facing away from the substrate; a leadless temperature sensor disposed on the pad of the semiconductor die; and a plurality of leads including a first lead electrically coupled with a surface of the leadless temperature sensor facing away from the surface of the semiconductor die and a second lead electrically coupled with the surface of the semiconductor die.

Example 5: The apparatus of any of the preceding examples, wherein: the transistor is a power metal-oxide-semiconductor field effect transistor (MOSFET), the power MOSFET including: a source pad implementing the pad of the semiconductor die on which the leadless temperature sensor is disposed, a gate pad on the surface of the semiconductor die facing away from the substrate and electrically isolated from the source pad, a sensor pad on the surface of the semiconductor die facing away from the substrate and electrically connected to the source pad, and a drain pad on a surface of the semiconductor die facing the substrate; and the second lead is electrically coupled with the sensor pad.

Example 6: The apparatus of any of the preceding examples, wherein the sensor pad is a Kelvin sense pad of the transistor.

Example 7: The apparatus of any of the preceding examples, wherein the leadless temperature sensor is a negative temperature coefficient (NTC) thermistor.

Example 8: The apparatus of any of the preceding examples, wherein: the semiconductor die is a first semiconductor die, the transistor is a first transistor, and the pad on the surface of the semiconductor die is a first pad; the apparatus further comprises a second semiconductor die disposed on the substrate, the second semiconductor die implementing a second transistor and including a second pad on a surface of the second semiconductor die facing away from the substrate; and the plurality of leads further includes a third lead electrically coupled with the surface of the second semiconductor die.

Example 9: The apparatus of any of the preceding examples, wherein: the leadless temperature sensor is a first leadless temperature sensor; the apparatus further comprises a second leadless temperature sensor disposed on the second pad of the second semiconductor die; and the plurality of leads further includes a fourth lead electrically coupled with a surface of the second leadless temperature sensor facing away from the surface of the second semiconductor die.

Example 10: The apparatus of any of the preceding examples, wherein the first semiconductor die and the second semiconductor die are hybrid dies fabricated using different semiconductors, the first semiconductor die being a silicon (Si) die and the second semiconductor die being a silicon carbide (SiC) die.

Example 11: The apparatus of any of the preceding examples, further comprising a molding compound that at least partially encapsulates the substrate, the semiconductor die, the leadless temperature sensor, and the plurality of leads.

Example 12: The apparatus of any of the preceding examples, wherein the substrate is a direct-bonded metal (DBM) substrate, the DBM substrate including a ceramic plate to which a patterned layer of conductive material is bonded on at least one side of the ceramic plate.

Example 13: The apparatus of any of the preceding examples, wherein the transistor is a power metal-oxide-semiconductor field effect transistor (MOSFET) fabricated using a silicon carbide (SiC) semiconductor.

Example 14: The apparatus of any of the preceding examples, wherein the surface of the leadless temperature sensor is coupled to the pad of the semiconductor die via a solder material or a sintering material.

Example 15: The apparatus of any of the preceding examples, wherein at least one of wires or clips are used to electrically couple the plurality of leads with other elements of the apparatus.

Example 16: The apparatus of any of the preceding examples, wherein the apparatus is an integrated circuit implementing a power module configured for use in an automotive application.

Example 17: A method comprising: coupling a semiconductor die with a substrate, the semiconductor die implementing a transistor and including a pad on a surface of the semiconductor die facing away from the substrate; coupling a leadless temperature sensor with the pad of the semiconductor die; coupling a first conductive component with a first lead of a plurality of leads and with a surface of the leadless temperature sensor facing away from the surface of the semiconductor die; and coupling a second conductive component with a second lead of the plurality of leads and with the surface of the semiconductor die.

Example 18: The method of any of the preceding examples, wherein: the transistor is a power metal-oxide-semiconductor field effect transistor (MOSFET), the power MOSFET including: a source pad implementing the pad of the semiconductor die on which the leadless temperature sensor is disposed, a gate pad on the surface of the semiconductor die facing away from the substrate and electrically isolated from the source pad, a sensor pad on the surface of the semiconductor die facing away from the substrate and electrically connected to the source pad, and a drain pad on a surface of the semiconductor die facing the substrate; and the coupling of the second conductive component with the surface of the semiconductor die is performed by coupling the second conductive component with the sensor pad.

Example 19: The method of any of the preceding examples, wherein: the leadless temperature sensor is a first leadless temperature sensor, the semiconductor die is a first semiconductor die, the transistor is a first transistor, and the pad on the surface of the semiconductor die is a first pad; and the method further comprises: coupling a second semiconductor die with the substrate, the second semiconductor die implementing a second transistor and including a second pad on a surface of the second semiconductor die facing away from the substrate, coupling a second leadless temperature sensor with the second pad of the second semiconductor die, coupling a third conductive component with a third lead of the plurality of leads and with the surface of the second semiconductor die, and coupling a fourth conductive component with a fourth lead of the plurality of leads and with a surface of the second leadless temperature sensor facing away from the surface of the second semiconductor die.

Example 20: The method of any of the preceding examples, wherein: the substrate is a direct-bonded metal (DBM) substrate, the DBM substrate including a ceramic plate to which a patterned layer of conductive material is bonded on at least one side of the ceramic plate; the transistor is a power metal-oxide-semiconductor field effect transistor (MOSFET) fabricated using a silicon carbide (SiC) semiconductor; and the method further comprises at least partially encapsulating, within a molding compound, the substrate, the semiconductor die, the leadless temperature sensor, and the plurality of leads.

A number of embodiments have been described. Nevertheless, it will be understood that various modifications may be made without departing from the spirit and scope of the specification.

It will also be understood that when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

The various apparatus and techniques described herein may be implemented using various semiconductor processing and/or packaging techniques. Some embodiments may be implemented using various types of semiconductor processing technologies associated with semiconductor substrates including, but not limited to, for example, Silicon (Si), Gallium Arsenide (GaAs), Silicon Carbide (SiC), and/or so forth.

It will also be understood that when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present.

Although the terms directly on, directly connected to, or directly coupled to may not be used throughout the detailed description, elements that are shown as being directly on, directly connected or directly coupled can be referred to as such. The claims of the application may be amended to recite illustrative relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

In addition, the logic flows depicted in the figures do not require the particular order shown, or sequential order, to achieve desirable results. In addition, other steps may be provided, or steps may be eliminated, from the described flows, and other components may be added to, or removed from, the described systems. Accordingly, other embodiments are within the scope of the following claims.

It will be understood that, although the terms first, second, etc. may be used herein to describe various elements, these elements should not be limited by these terms. These terms are only used to distinguish one element from another. A first element could be termed a second element, and, similarly, a second element could be termed a first element, without departing from the scope of the implementations of the disclosure. As used herein, the term and/or includes any and all combinations of one or more of the associated listed items.

While certain features of the described implementations have been illustrated as described herein, many modifications, substitutions, changes, and equivalents may occur to those skilled in the art. It is therefore to be understood that the appended claims are intended to cover such modifications and changes as fall within the scope of the implementations. It will be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components, and/or features of the different implementations described. As such, the scope of the present disclosure is not limited to the particular combinations hereafter claimed, but instead extends to encompass any combination of features or example implementations described herein irrespective of whether or not that particular combination has been specifically enumerated in the accompanying claims at this time.

What is claimed is:

1. An apparatus comprising:
a substrate;
a semiconductor die disposed on the substrate, the semiconductor die implementing a transistor;
a leadless temperature sensor having a first surface and a second surface opposite the first surface, the leadless temperature sensor being configured to measure a temperature of the semiconductor die; and
a plurality of leads including a first lead and a second lead, the first lead electrically coupled with the first surface of the leadless temperature sensor and the second lead electrically coupled with the second surface of the leadless temperature sensor.

2. The apparatus of claim 1, wherein:
the leadless temperature sensor is disposed on a pad of a surface of the semiconductor die facing away from the substrate, the second surface of the leadless temperature sensor being physically coupled to the pad; and
the second lead is electrically coupled with the second surface of the leadless temperature sensor by being coupled to the surface of the semiconductor die.

3. The apparatus of claim 1, wherein:
the substrate includes a first portion and a second portion, the first portion being electrically isolated from the second portion;
the leadless temperature sensor is disposed on the first portion and the semiconductor die is disposed on the second portion; and
the second lead is electrically coupled with the second surface of the leadless temperature sensor by being coupled to the second portion of the substrate.

4. An apparatus comprising:
a substrate;
a semiconductor die disposed on the substrate, the semiconductor die implementing a transistor and including a pad on a surface of the semiconductor die facing away from the substrate;
a leadless temperature sensor disposed on the pad of the semiconductor die; and
a plurality of leads including a first lead electrically coupled with a surface of the leadless temperature sensor facing away from the surface of the semiconductor die and a second lead electrically coupled with the surface of the semiconductor die.

5. The apparatus of claim 4, wherein:
the transistor is a power metal-oxide-semiconductor field effect transistor (MOSFET), the power MOSFET including:
a source pad implementing the pad of the semiconductor die on which the leadless temperature sensor is disposed,
a gate pad on the surface of the semiconductor die facing away from the substrate and electrically isolated from the source pad,
a sensor pad on the surface of the semiconductor die facing away from the substrate and electrically connected to the source pad, and
a drain pad on a surface of the semiconductor die facing the substrate; and
the second lead is electrically coupled with the sensor pad.

6. The apparatus of claim 5, wherein the sensor pad is a Kelvin sense pad of the transistor.

7. The apparatus of claim 4, wherein the leadless temperature sensor is a negative temperature coefficient (NTC) thermistor.

8. The apparatus of claim 4, wherein:
the semiconductor die is a first semiconductor die, the transistor is a first transistor, and the pad on the surface of the semiconductor die is a first pad;
the apparatus further comprises a second semiconductor die disposed on the substrate, the second semiconductor die implementing a second transistor and including a second pad on a surface of the second semiconductor die facing away from the substrate; and
the plurality of leads further includes a third lead electrically coupled with the surface of the second semiconductor die.

9. The apparatus of claim 8, wherein:
the leadless temperature sensor is a first leadless temperature sensor;
the apparatus further comprises a second leadless temperature sensor disposed on the second pad of the second semiconductor die; and
the plurality of leads further includes a fourth lead electrically coupled with a surface of the second leadless temperature sensor facing away from the surface of the second semiconductor die.

10. The apparatus of claim 8, wherein the first semiconductor die and the second semiconductor die are hybrid dies fabricated using different semiconductors, the first semiconductor die being a silicon (Si) die and the second semiconductor die being a silicon carbide (SiC) die.

11. The apparatus of claim 4, further comprising a molding compound that at least partially encapsulates the substrate, the semiconductor die, the leadless temperature sensor, and the plurality of leads.

12. The apparatus of claim 4, wherein the substrate is a direct-bonded metal (DBM) substrate, the DBM substrate including a ceramic plate to which a patterned layer of conductive material is bonded on at least one side of the ceramic plate.

13. The apparatus of claim 4, wherein the transistor is a power metal-oxide-semiconductor field effect transistor (MOSFET) fabricated using a silicon carbide (SiC) semiconductor.

14. The apparatus of claim 4, wherein the surface of the leadless temperature sensor is coupled to the pad of the semiconductor die via a solder material or a sintering material.

15. The apparatus of claim 4, wherein at least one of wires or clips are used to electrically couple the plurality of leads with other elements of the apparatus.

16. The apparatus of claim 4, wherein the apparatus is an integrated circuit implementing a power module configured for use in an automotive application.

17. A method comprising:
coupling a semiconductor die with a substrate, the semiconductor die implementing a transistor and including a pad on a surface of the semiconductor die facing away from the substrate;
coupling a leadless temperature sensor with the pad of the semiconductor die;
coupling a first conductive component with a first lead of a plurality of leads and with a surface of the leadless temperature sensor facing away from the surface of the semiconductor die; and
coupling a second conductive component with a second lead of the plurality of leads and with the surface of the semiconductor die.

18. The method of claim 17, wherein:
the transistor is a power metal-oxide-semiconductor field effect transistor (MOSFET), the power MOSFET including:
a source pad implementing the pad of the semiconductor die on which the leadless temperature sensor is disposed,
a gate pad on the surface of the semiconductor die facing away from the substrate and electrically isolated from the source pad,
a sensor pad on the surface of the semiconductor die facing away from the substrate and electrically connected to the source pad, and
a drain pad on a surface of the semiconductor die facing the substrate; and
the coupling of the second conductive component with the surface of the semiconductor die is performed by coupling the second conductive component with the sensor pad.

19. The method of claim 17, wherein:
the leadless temperature sensor is a first leadless temperature sensor, the semiconductor die is a first semiconductor die, the transistor is a first transistor, and the pad on the surface of the semiconductor die is a first pad; and
the method further comprises:
coupling a second semiconductor die with the substrate, the second semiconductor die implementing a second transistor and including a second pad on a surface of the second semiconductor die facing away from the substrate,
coupling a second leadless temperature sensor with the second pad of the second semiconductor die,
coupling a third conductive component with a third lead of the plurality of leads and with the surface of the second semiconductor die, and
coupling a fourth conductive component with a fourth lead of the plurality of leads and with a surface of the second leadless temperature sensor facing away from the surface of the second semiconductor die.

20. The method of claim 17, wherein:
the substrate is a direct-bonded metal (DBM) substrate, the DBM substrate including a ceramic plate to which a patterned layer of conductive material is bonded on at least one side of the ceramic plate;
the transistor is a power metal-oxide-semiconductor field effect transistor (MOSFET) fabricated using a silicon carbide (SiC) semiconductor; and
the method further comprises at least partially encapsulating, within a molding compound, the substrate, the semiconductor die, the leadless temperature sensor, and the plurality of leads.
